(19) United States
(12) Patent Application Publication
(10) Pub. No.: US 2026/0251972 A1
(43) Pub. Date: Aug. 27, 2026

(54) PHOTOSENSITIVE RESIN COMPOSITION, PHOTOSENSITIVE RESIN FILM, MULTILAYER PRINTED WIRING BOARD, SEMICONDUCTOR PACKAGE, AND METHOD FOR MANUFACTURING MULTILAYER PRINTED WIRING BOARD

(71) Applicant: Resonac Corporation, Minato-ku, Tokyo (JP)

(72) Inventors: Yuko KONNO, Minato-ku, Tokyo (JP); Hideyuki KATAGI, Minato-ku, Tokyo (JP); Kumpei YAMADA, Minato-ku, Tokyo (JP); Takeshi NOJIRI, Minato-ku, Tokyo (JP)

(21) Appl. No.: 18/855,825

(22) PCT Filed: Mar. 8, 2023
(86) PCT No.: PCT/JP2023/008746

§ 371 Date: Oct. 10, 2024

(51) Int. Cl. G03F 7/031; G03F 7/029; G03F 7/032; H10W 70/05; H10W 70/695

(52) U.S. Cl. CPC G03F 7/031; G03F 7/029; G03F 7/032; H10W 70/05; H10W 70/695

(57) ABSTRACT

Provided is a photosensitive resin composition containing (X) an inorganic filler that is solid particles having a true density of 1,500 kg/m³ or less. Also provided is a photosensitive resin film formed by using the photosensitive resin composition. Further provided is a multilayered printed wiring board containing an interlayer insulating layer that is formed by using the photosensitive resin composition or the photosensitive resin film and a method for producing the multilayered printed wiring board. Furthermore provided is a semiconductor package including the multilayered printed wiring board and a semiconductor element.

### TECHNICAL FIELD

The present disclosure relates to a photosensitive resin composition, a photosensitive resin film, a multilayered printed wiring board and a semiconductor package, and a method for producing a multilayered printed wiring board.

### BACKGROUND ART

In recent years, miniaturization and increase in performance of electronic instruments have been advanced, and in multilayered printed wiring boards, densification owing to an increase in the number of circuit layers and miniaturization of wiring has proceeded. In particular, densification of a semiconductor package substrate on which semiconductor chips are mounted, such as BGA (ball grid array) and CSP (chip size package), is conspicuous, and in addition to the miniaturization of wiring, thinning of an insulating layer and more reduction in diameter of a via for interlayer connection (also referred to as “via hole”) are demanded.

As a production method of a printed wiring board which has conventionally been employed, there is exemplified a production method of a multilayered printed wiring board by a build-up method in which an interlayer insulating layer and a conductor circuit layer are successively laminated to form a multilayered printed wiring board (see, for example, PTL 1). In the multilayered printed wiring board, in association with the miniaturization of a circuit, a semi-additive process in which a circuit is formed by means of plating has become the mainstream.

In the conventional semi-additive process, for example, (1) a thermosetting resin film is laminated on a conductor circuit, followed by curing the thermosetting resin film by heating, to form an “interlayer insulating layer”. (2) Subsequently, a via for interlayer connection is formed by means of laser processing, followed by performing a desmear treatment and a roughening treatment by means of an alkaline permanganate treatment, or the like. (3) Thereafter, a substrate is subjected to an electroless copper plating treatment, and then, a pattern is formed using a resist, followed by performing an electrolytic copper plating treatment, to form a copper circuit layer. (4) Subsequently, resist is stripped, followed by performing flash etching of an electroless layer, whereby a copper circuit is formed.

As mentioned above, the laser processing is the mainstream of methods for forming a via in the interlayer insulating layer formed by curing a thermosetting resin film. However, the reduction in diameter of a via by means of laser irradiation using a laser processing machine is reaching the limit. Furthermore, in forming a via by a laser processing machine, multiple via holes have to be formed one by one, and in the case where it is necessary to form a large number of vias due to densification, there is involved such a problem that a lot of time is required for forming the vias, so that the production efficiency is poor.

Under such circumstances, as a method in which a large number of vias can be collectively formed, there is proposed a method of collectively forming a plurality of small-diameter vias by a photolithography method by using a photosensitive resin composition which contains an acid-modified vinyl group-containing epoxy resin, a photopolymerizable compound, a photopolymerization initiator, an inorganic filler, and a silane compound, the inorganic filler being contained in an amount of 10 to 80% by mass (see, for example, PTL 2).

In PTL 2, one of problems is presumed as suppression of reduction in adhesion with copper plating attributable to use of a photosensitive resin composition in place of a conventional thermosetting resin composition as a material of an interlayer insulating layer or a surface protection layer, and further problems are presumed as resolution of vias and adhesiveness of a silicone material with a substrate and chip parts. Then, it is insisted that the problems have been solved.

In recent years, a substrate material has been required to be applied to the 5th Generation Mobile Communication System (5G) antenna in which radio waves in a high frequency band are used and a millimeter wave radar in which radio waves in a higher frequency band are used. For coping with this situation, as one of goals, it is necessary to develop a resin composition that has a furthermore improved dielectric constant in the “10 GHz band”. However, in the technique of PTL 2, there is room for improvement in the dielectric constant in the 10 GHz band.

### CITATION LIST

### Patent Literature

PTL 1: JP 7-304931 A
PTL 2: JP 2017-116652 A

### SUMMARY OF INVENTION

### Technical Problem

The present inventors examined, for reducing the dielectric constant in the 10 GHz band, incorporation of polytetrafluoroethylene (hereinafter referred to as PTFE) particles which have a very low dielectric constant into a photosensitive resin composition. However, it has been found that, when PTFE is simply incorporated in a photosensitive resin composition, the dielectric constant can indeed be reduced, but there arises a problem of reduction in the adhesion strength to copper plating, and it is difficult to achieve both the dielectric constant in the 10 GHz band and the adhesion strength to copper plating.

Thus, an object of the present disclosure is to provide a photosensitive resin composition that exhibits a superior dielectric constant in the 10 GHz band and a high adhesion strength to copper plating and a photosensitive resin film formed by using the photosensitive resin composition, and to provide a multilayered printed wiring board and a method for producing the same, and a semiconductor package.

### Solution to Problem

As a result of intensive and extensive studies, the present inventors have found that the object can be achieved by the present disclosure.

The present disclosure includes the following embodiments [1] to [18].
[1]A photosensitive resin composition containing (X) an inorganic filler that is solid particles having a true density of 1,500 kg/m³ or less.
[2] The photosensitive resin composition according to the above [1], in which the component (X) has a volume average particle size of 0.3 to 3 μm.
[3] The photosensitive resin composition according to the above [1] or [2], in which the component (X) is contained in an amount of 1 to 45% by volume based on a total amount of solid components in the photosensitive resin composition.
[4] The photosensitive resin composition according to any one of the above [1] to [3], further containing (A) a photopolymerizable compound having an ethylenically unsaturated group and an acidic substituent and (B) a thermosetting resin.
[5] The photosensitive resin composition according to the above [4], in which the component (A) contains an alicyclic skeleton represented by the following general formula (A-1):

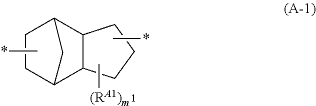

in which R^{A1} represents an alkyl group having 1 to 12 carbon atoms and may be substituted on any site in the alicyclic skeleton, m¹ is an integer of 0 to 6, and * is a bonding site to another structure.
[6] The photosensitive resin composition according to the above [4] or [5], in which the photosensitive resin composition has an equivalent ratio of an epoxy group of the component (B) to the acidic substituent of the component (A) [epoxy group/acidic substituent] of 0.5 to 6.0.
[7] The photosensitive resin composition according to any one of the above [1] to [6], further containing (C) a crosslinking agent.
[8] The photosensitive resin composition according to any one of the above [1] to [7], further containing (D) an elastomer.
[9] The photosensitive resin composition according to any one of the above [1] to [8], further containing (E) an organic filler.
[10] The photosensitive resin composition according to the above [9], in which the component (E) contains resin particles formed of at least one selected from the group consisting of a resin having a fluorine atom, polyethylene, polypropylene, polystyrene, polyphenylene ether, and a silicone.
[11] The photosensitive resin composition according to the above [9] or [10], in which the component (E) is contained in an amount of 1 to 45% by volume based on a total amount of solid components in the photosensitive resin composition.
[12] The photosensitive resin composition according to any one of the above [1] to [11], further containing (H) a photopolymerization initiator.
[13] The photosensitive resin composition according to the above [12], in which two or more kinds of the component (H) are contained.
[14]A photosensitive resin composition for photo-via formation, formed of the photosensitive resin composition according to any one of the above [1] to [13].
[15]A photosensitive resin film formed by using the photosensitive resin composition according to any one of the above [1] to [13].
[16]A multilayered printed wiring board containing an interlayer insulating layer that is formed by using the photosensitive resin composition according to any one of the above [1] to [13] or the photosensitive resin film according to the above [15].
[17]A semiconductor package including the multilayered printed wiring board according to the above [16] and a semiconductor element.
[18]A method for producing a multilayered printed wiring board, the method including the following (1), (2), and (4):
(1): laminating the photosensitive resin film according to the above [15] on one surface or both surfaces of a circuit substrate;
(2): exposing and developing the photosensitive resin film laminated in (1) to thereby form an interlayer insulating layer having a via;
(4): forming a circuit pattern on the interlayer insulating layer.

### Advantageous Effects of Invention

According to the present disclosure, it is possible to provide a photosensitive resin composition that exhibits a superior dielectric constant in the 10 GHz band and a high adhesion strength to copper plating. It is also possible to provide a photosensitive resin film formed by using the photosensitive resin composition. Then, it is possible to provide a multilayered printed wiring board that contains an interlayer insulating layer formed by using the photosensitive resin composition or the photosensitive resin film, and it is also possible to provide a method for producing the multilayered printed wiring board. It is further possible to provide a semiconductor package that includes the multilayered printed wiring board and a semiconductor element.

### BRIEF DESCRIPTION OF DRAWINGS

FIG. 1 is a schematic diagram illustrating an aspect of a production process of a multilayered printed wiring board in which the photosensitive resin film of this embodiment is used as a material of at least one of a surface protection layer and an interlayer insulating layer.

### DESCRIPTION OF EMBODIMENTS

In numerical value ranges described in the present description, upper limit values or lower limit values in the numerical value ranges may each be substituted by a value described in Examples. In addition, lower limit values and upper limit values of the numerical value ranges are each arbitrarily combined with a lower limit value or an upper limit value of another numerical value range. In the notation of the numerical range “AA to BB”, the numerical values AA and BB at both ends are included in the numerical range as the lower limit value and the upper limit value, respectively.

In the present description, for example, the description of “10 or more” means 10 and numerical values exceeding 10, and the same applies to cases of different numerical values. Further, for example, the description “10 or less” means 10 and numerical values less than 10, and the same applies to cases of different numerical values.

In the present description, as for the content of each component in the photosensitive resin composition, in the case where there are two or more substances that correspond to the component, the content means the total content of the two or more substances present in the photosensitive resin composition unless otherwise indicated.

The term “number of ring carbon atoms” in the present description is the number of carbon atoms necessary for forming the ring, and the number of carbon atoms of a substituent that the ring has is not included. For example, in both a cyclohexane skeleton and a methylcyclohexane skeleton, the number of ring carbon atoms is 6.

The expression “(meth)acrylic XX” means one or both of acrylic XX and its corresponding methacrylic XX. Further, the expression “(meth)acryloyl group” means one or both of an acryloyl group and a methacryloyl group.

In the present description, the term “dielectric constant” means the dielectric constant in the 10 GHz band even with no particular description.

Aspects of any combination of the matters described in the present description are also included in the present embodiment.

### [Photosensitive Resin Composition]

A photosensitive resin composition according to an embodiment of the present disclosure (hereinafter sometimes referred to simply as this embodiment) is a photosensitive resin composition that contains (X) an inorganic filler that is solid particles having a true density of 1,500 kg/m³ or less.

Here, in the present description, this component is sometimes abbreviated as “component (X)” and other components are sometimes abbreviated in the same manner.

In the present description, the “resin component” refers to a component (A), a component (B), and the like to be described later, and also encompasses other components (for example, components (C), (D), (E), (F), (G), (H), (I), and the like) which may be contained as required, but does not encompass inorganic compounds, such as the component (X), other inorganic fillers, and pigments. The “solid components” refer to non-volatile components excluding water and a diluent to be described later, contained in the photosensitive resin composition, and encompasses a substance that is in a liquid, syrup, and wax form at a room temperature around 25° C.

The photosensitive resin composition of this embodiment is superior in the dielectric constant in the 10 GHz band and is suited to via formation by photolithography (also referred to as photo-via formation), and thus, is suitable for formation of one or more selected from the group consisting of a photo-via and an interlayer insulating layer. Here, in the present disclosure, in the case where there is a notation of “layer”, for example, as in an interlayer insulating layer, the “layer” encompasses, in addition to an aspect of a solid layer, an aspect that is not a solid layer but includes an island form at least in a part, an aspect having a hole, and a case where the interface with respect to an adjacent layer is unclear. The solid layer means a layer of a sheet form which has not particularly been subjected to any processing.

The photosensitive resin composition of this embodiment is suitable for a negative-type photosensitive resin composition.

Hereinunder, the component (X) will be described in detail, and then, the other components that the photosensitive resin composition of this embodiment may contain will be described.

<(X) Inorganic Filler that is Solid Particles Having a True Density of 1,500 kg/m³ or Less>

The photosensitive resin composition of this embodiment contains, as a component (X), an inorganic filler that is solid particles having a true density of 1,500 kg/m³ or less, thereby exhibiting a superior dielectric constant in the 10 GHz band and a high adhesion strength to copper plating. Here, the true density of the component (X) is a value measured by a dry automatic density meter “AccuPycII 1340” (manufactured by SHIMADZU CORPORATION), and more specifically, a value measured according to a method described in the section of Examples. In the present disclosure, the term “solid particles” refers to particles that has a hollow rate determined based on the true density measured with the dry automatic density meter (specifically, by a method described in the section of Examples) of 60% or less (including 0%, that is, 0 to 60%). When the hollow rate measured by this method is more than 60%, such particles are referred to as “hollow particles”. Thus, for example, even if particles have porous interior, when the hollow rate thereof is 60% or less, the particles are encompassed in solid particles.

The hollow rate of solid particles is, from the viewpoints of dielectric constant and adhesion strength to copper plating, preferably 55% or less, more preferably 50% or less, further preferably 45% or less, and particularly preferably 43% or less. The lower limit of the hollow rate is not particularly limited, and may be 0% or more, may be 5% or more, may be 15% or more, may be 25% or more, may be 30% or more, may be 32% or more, may be 34% or more, or may be 37% or more. The hollow rate is determined as described in the section of Examples.

A correct mechanism of exhibiting the superior dielectric constant and high adhesion strength to copper plating is not clear, but it is supposed as follow. Since the true density was 1,500 kg/m³ or less, the space in the inorganic filler that was solid particles at a molecular level was increased, which led to reduction in the dielectric constant. In addition, since the component (X) was an inorganic filler, a considerable decrease in the adhesion strength to copper plating like in PTFE does not occur, and hence, reduction in the dielectric constant and a high adhesion strength to copper plating could both be achieved. However, this supposition is not to limit the scope of the photosensitive resin composition of this embodiment.

The true density of the component (X) is, from the viewpoints of dielectric constant and adhesion strength to copper plating, preferably 1,000 to 1,500 kg/m³, more preferably 1,100 to 1,500 kg/m³, further preferably 1,200 to 1,500 kg/m³, particularly preferably 1,250 to 1,450 kg/m³, and most preferably 1,250 to 1,400 kg/m³.

Examples of the component (X) include silica (SiO₂), alumina (Al₂O₃), titania (TiO₂), tantalum oxide (Ta₂O₅), zirconia (ZrO₂), silicon nitride (Si₃N₄), barium titanate (BaO—TiO₂), barium carbonate (BaCO₃), magnesium carbonate (MgCO₃), aluminum hydroxide (Al(OH)₃), magnesium hydroxide (Mg(OH)₂), lead titanate (PbO—TiO₂), lead zirconate titanate (PZT), lead lanthanum zirconate titanate (PLZT), gallium oxide (Ga₂O₃), spinel (MgO—Al₂O₃), mullite (3Al₂O₃-2SiO₂), cordierite (2MgO-2Al₂O₃/5SiO₂), talc (3MgO-4SiO₂—H₂O), aluminum titanate (TiO₂—Al₂O₃), yttria-containing zirconia (Y₂O₃—ZrO₂), barium silicate (BaO-8SiO₂), boron nitride (BN), calcium carbonate (CaCO₃), barium sulfate (BaSO₄), calcium sulfate (CaSO₄), zinc oxide (ZnO), magnesium titanate (MgO—TiO₂), hydrotalcite, mica, calcined kaolin, and carbon (C). Among them, from the viewpoints of heat resistance, low thermal expansion, and dielectric constant, silica is preferred.

As the component (X), a commercial product can be used. Examples of the silica that is solid particles having a true density of 1,500 kg/m³ or less include “BQQ-0710SCB” (manufactured by TAT) and “BQQ-0310SCB” (manufactured by TAT). The silica that is solid particles having a true density of 1,500 kg/m³ or less is not particularly limited, but preferably has, besides an Si—O-bond, an Si—R^{X} bond (RX represents an organic group).

From the viewpoint of improving dispersibility in the photosensitive resin composition, the component (X) may be one surface-treated with a coupling agent or may be one not surface-treated with a coupling agent, but is preferably one surface-treated with a coupling agent. Examples of the coupling agent include silane coupling agents, such as an aminosilane-based coupling agent, an epoxysilane-based coupling agent, a phenylsilane-based coupling agent, an alkylsilane-based coupling agent, an alkenylsilane-based coupling agent, an alkinylsilane-based coupling agent, a haloalkylsilane-based coupling agent, a siloxane-based coupling agent, a hydrosilane-based coupling agent, a silazane-based coupling agent, an alkoxysilane-based coupling agent, a chlorosilane-based coupling agent, a (meth)acrylsilane-based coupling agent, an isocyanuratesilane-based coupling agent, an ureidosilane-based coupling agent, a mercaptosilane-based coupling agent, a sulfidesilane-based coupling agent, and an isocyanatesilane-based coupling agent.

The volume average particle size of the component (X) is preferably 0.3 to 3 μm, more preferably 0.3 to 2.5 μm, further preferably 0.3 to 2.0 μm, particularly preferably 0.3 to 1.7 μm, and may be 0.3 to 1.2 μm, or may be 1.2 to 2.0 μm. When the volume average particle size of the component (X) is the lower limit or more, the low thermal expansion tends to be superior, and when it is the upper limit or less, the resolution of vias tends to be superior. When the volume average particle size of the component (X) is 2.5 μm or less, the resolution of vias tends to be considerably improved.

From the viewpoints of improving the adhesion to copper plating and the resolution of vias, two or more kinds of inorganic fillers having different volume average particle sizes may be used in combination as the component (X).

Here, the volume average particle size can be determined as follows: particles dispersed in a solvent are measured using a submicron particle analyzer (manufactured by Beckman Coulter, Inc., tradename: N5) according to ISO13321 at a refractive index of 1.38 to determine the particle size corresponding to a cumulative value of 50% (by volume) in a particle size distribution and the obtained particle size is taken as the volume average particle size.

In the photosensitive resin composition of this embodiment, the content of the component (X) is not particularly limited, but is, based on the total amount of solid components in the photosensitive resin composition, preferably 1 to 45% by volume, more preferably 3 to 40% by volume, further preferably 5 to 40% by volume, and may be 5 to 25% by volume, or may be 25 to 40% by volume. When the content of the component (X) is the lower limit or more, a lower dielectric constant and coefficient of thermal expansion tend to be achieved, and when the content is the upper limit or less, a more superior adhesion strength to copper plating and resolution of vias tend to be achieved.

The photosensitive resin composition of this embodiment preferably further contains (A) a photopolymerizable compound having an ethylenically unsaturated group and an acidic substituent and (B) a thermosetting resin. Hereinunder, the component (A) and the component (B) will be described in detail in order, and then, other components will also be described in detail.

### <(A) Photopolymerizable Compound Having an Ethylenically Unsaturated Group and an Acidic Substituent>

The component (A) is a photopolymerizable compound having an ethylenically unsaturated group and an acidic substituent.

As the component (A), one kind may be used alone or two or more kinds may be used in combination.

The component (A) has an ethylenically unsaturated group, and thus, is a compound that exhibits photopolymerizability, in particular, radical polymerizability.

Examples of the ethylenically unsaturated group of the component (A) include photopolymerizable functional groups, such as a vinyl group, an allyl group, a propargyl group, a butenyl group, an ethynyl group, a phenylethynyl group, a maleimide group, a nadimide group, and a (meth)acryloyl group. Among them, from the viewpoints of reactivity and resolution of vias, a (meth)acryloyl group is preferred.

From the viewpoints of capability of alkaline development, the component (A) has an acidic substituent.

Examples of the acidic substituent of the component (A) include a carboxy group, a sulfonate group, and a phenolic hydroxy group. Among them, from the viewpoint of resolution of vias, a carboxy group is preferred.

The acid value of the component (A) is preferably 20 to 200 mgKOH/g, more preferably 40 to 180 mgKOH/g, further preferably 70 to 150 mgKOH/g, and particularly preferably 90 to 120 mgKOH/g. When the acid value of the component (A) is the lower limit or more, the solubility of a photosensitive resin film in a dilute alkali solution tends to be superior, and when the acid value is the upper limit or less, the dielectric constant tend to be superior. The acid value of the component (A) can be measured by a method described in the section of Examples.

Two or more kinds of the component (A) having different acid values may be used in combination, and in this case, the acid value which is the weighted mean of the acid values of the two or more kinds of the component (A) is preferably within any range of the aforementioned ranges.

The weight average molecular weight (Mw) of the component (A) is preferably 600 to 30,000, more preferably 800 to 25,000, further preferably 1,000 to 18,000, furthermore preferably 1,000 to 8,000, particularly preferably 1,200 to 5,000, and most preferably 1,200 to 3,500. When the weight average molecular weight (Mw) of the component (A) is within the above range, the adhesion strength to copper plating, the heat resistance, and the insulation reliability tend to be superior. Here, in the present description, the weight average molecular weight is a value determined by calculation based on standard polystyrenes according to gel permeation chromatography (GPC) using tetrahydrofuran as a solvent, and specifically, a value measured according to a method described in the section of Examples.

From the viewpoints of dielectric constant, the component (A) preferably contains an alicyclic skeleton.

The alicyclic skeleton of the component (A) is, from the viewpoints of resolution of vias, adhesion strength to copper plating, and electrical insulation reliability, preferably an alicyclic skeleton having 5 to 20 ring carbon atoms, more preferably an alicyclic skeleton having 5 to 18 ring carbon atoms, further preferably an alicyclic skeleton having 6 to 18 ring carbon atoms, particularly preferably an alicyclic skeleton having 8 to 14 ring carbon atoms, and most preferably an alicyclic skeleton having 8 to 12 ring carbon atoms.

From the viewpoints of resolution of vias, the adhesion strength to copper plating, and the electrical insulation reliability, the alicyclic skeleton is preferably composed of two or more rings, more preferably composed of 2 to 4 rings, and further preferably composed of 3 rings. Examples of the alicyclic skeleton having two or more rings include a norbornane skeleton, a decalin skeleton, a bicycloundecane skeleton, and a saturated dicyclopentadiene skeleton. Among them, from the viewpoints of resolution of vias, adhesion strength to copper plating, and electrical insulation reliability, a saturated dicyclopentadiene skeleton is preferred.

From the same point of view, the component (A) is preferably a compound containing an alicyclic skeleton represented by the following general formula (A-1).

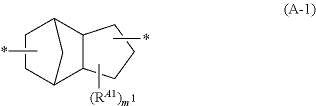

(In the formula, R^{A1} represents an alkyl group having 1 to 12 carbon atoms and may be substituted on any site in the alicyclic skeleton, m¹ is an integer of 0 to 6, and * is a bonding site to another structure.)

In the general formula (A-1), examples of the alkyl group having 1 to 12 carbon atoms represented by R^{A1} include a methyl group, an ethyl group, an n-propyl group, an isopropyl group, an n-butyl group, an isobutyl group, a t-butyl group, and an n-pentyl group. The alkyl group is preferably an alkyl group having 1 to 6 carbon atoms, more preferably an alkyl group having 1 to 3 carbon atoms, and further preferably a methyl group.

m¹ is an integer of 0 to 6, preferably an integer of 0 to 2, and more preferably 0.

When m¹ is an integer of 2 to 6, the two or more R^{A1}'s may be the same as or different from one another. Furthermore, the two or more R^{A1}'s may be substituted on the same carbon atom to the extent possible, or may be substituted on different carbon atoms.

* is a bonding site to another structure and may be bonded at any carbon atom on the alicyclic skeleton, but may be preferably bonded at the carbon atom of the site represented by 1 or 2 and the carbon atom of the site represented by 3 or 4 in the following general formula (A-1′).

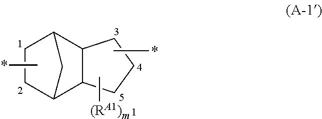

(In the formula, R^{A1}, m¹, and * are the same as in the general formula (A-1).)

From the viewpoints of resolution of vias and adhesion strength to copper plating, the component (A) is preferably an acid-modified vinyl group-containing epoxy resin obtained by allowing (a3) a saturated group or unsaturated group-containing polybasic acid anhydride to react with a compound [hereinafter sometimes referred to as component (A′)] which is obtained by modifying (a1) an epoxy resin with (a2) an ethylenically unsaturated group-containing organic acid. Here, the “acid-modified” in the acid-modified vinyl group-containing epoxy resin means having an acidic substituent, the “vinyl group” means an ethylenically unsaturated group, and the “epoxy resin” means using an epoxy resin as a raw material. The acid-modified vinyl group-containing epoxy resin is not necessarily required to have an epoxy group and may have no epoxy group.

Hereinunder, a suitable aspect of the component (A) which is obtained from the epoxy resin (a1), the ethylenically unsaturated group-containing organic acid (a2) and the saturated group or unsaturated group-containing polybasic acid anhydride (a3) will be described.

((a1) Epoxy Resin)

The epoxy resin (a1) is preferably an epoxy resin having two or more epoxy groups.

As the epoxy resin (a1), one kind may be used alone or two or more kinds may be used in combination.

The epoxy resin (a1) is divided into glycidyl ether-type epoxy resins, glycidyl amine-type epoxy resins, glycidyl ester-type epoxy resins, and the like. Among them, a glycidyl ether-type epoxy resin is preferred.

The epoxy resin (a1) can also be classified into various epoxy resins depending on the difference in the main skeleton, and can be classified into epoxy resins having an alicyclic skeleton, novolac-type epoxy resins, bisphenol-type epoxy resins, aralkyl-type epoxy resins, and other epoxy resins. Among them, an epoxy resin having an alicyclic skeleton and a novolac-type epoxy resin are preferred.

### —Epoxy Resin Having Alicyclic Skeleton—

The alicyclic skeleton of the epoxy resin having an alicyclic skeleton is explained in the same manner as for the aforementioned alicyclic skeleton of the component (A), and the preferred aspect is also the same.

The epoxy resin having an alicyclic skeleton is preferably an epoxy resin represented by the following general formula (A-2).

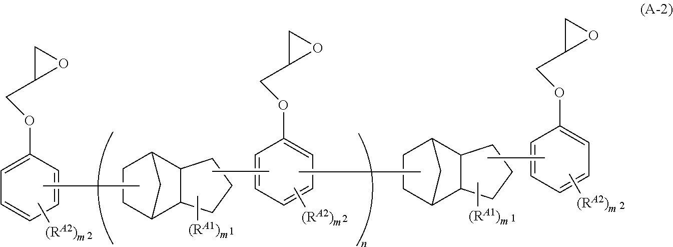

(In the formula, R^{A1} represents an alkyl group having 1 to 12 carbon atoms and may be substituted on any site in the alicyclic skeleton, R^{A2} represents an alkyl group having 1 to 12 carbon atoms, m¹ is an integer of 0 to 6, m² is an integer of 0 to 3, and n is a number of 0 to 50.)

In the general formula (A-2), R^{A1} is the same as R^{A1} in the general formula (A-1), and the preferred aspect is also the same.

Examples of the alkyl group having 1 to 12 carbon atoms represented by R^{A2} in the general formula (A-2) include a methyl group, an ethyl group, an n-propyl group, an isopropyl group, an n-butyl group, an isobutyl group, a t-butyl group, and an n-pentyl group. The alkyl group is preferably an alkyl group having 1 to 6 carbon atoms, more preferably an alkyl group having 1 to 3 carbon atoms, and further preferably a methyl group.

m¹ in the general formula (A-2) is the same as m¹ in the general formula (A-1), and the preferred aspect is also the same.

m² in the general formula (A-2) is an integer of 0 to 3, preferably 0 or 1, and more preferably 0.

n in the general formula (A-2) represents the number of repetitions of the structural unit in the parentheses and a number of 0 to 50. Since an epoxy resin is generally a mixture of compounds having different numbers of repetitions of the structural unit in the parentheses, in this case, n is represented by the average in the mixture. n is preferably a number of 0 to 30.

As the epoxy resin having an alicyclic skeleton, a commercial product may be used, and examples thereof include XD-1000 (tradename, manufactured by Nippon Kayaku Co., Ltd.) and EPICLON (registered tradename) HP-7200 (tradename, manufactured by DIC Corporation).

### —Novolak-Type Epoxy Resin—

Examples of the novolak-type epoxy resin include bisphenol novolak-type epoxy resins, such as a bisphenol A novolak-type epoxy resin, a bisphenol F novolak-type epoxy resin, and a bisphenol S novolak-type epoxy resin; a phenol novolak-type epoxy resin, a cresol novolak-type epoxy resin, a biphenyl novolak-type epoxy resin, and a naphthol novolak-type epoxy resin.

The novolak-type epoxy resin is preferably an epoxy resin having a structural unit represented by the following general formula (A-3).

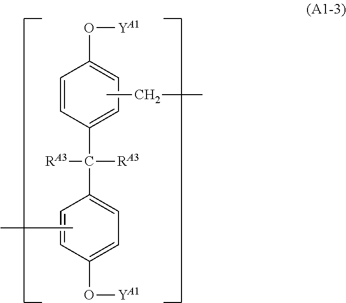

(In the formula, R^{A3} represents a hydrogen atom or a methyl group, Y^{A1}'s each independently represent a hydrogen atom or a glycidyl group, two R^{A3}'s may be the same as or different from each other, and at least one of two Y^{A1}'s represents a glycidyl group.)

From the viewpoints of resolution of vias and adhesion strength to copper plating, each R^{A3} is preferably a hydrogen atom. From the same point of view, each YA is preferably a glycidyl group.

In the epoxy resin (a1) having a structural unit represented by the general formula (A-3), the number of the structural units is a number of 1 or more, preferably a number of 10 to 100, more preferably a number of 15 to 80, and further preferably a number of 15 to 70. When the number of the structural units is within the above range, the adhesion strength to copper plating, heat resistance, and insulation reliability tend to be improved.

In the general formula (A-3), a compound in which each R^{A3} is a hydrogen atom and each Y^{A1} is a glycidyl group is commercially available as EXA-7376 series (tradename, manufactured by DIC Corporation). A compound in which each R^{A3} is a methyl group and each Y^{A1} is a glycidyl group is commercially available as EPON SU8 series (tradename, manufactured by Mitsubishi Chemical Corporation).

Examples of the bisphenol-type epoxy resin include a bisphenol A-type epoxy resin, a bisphenol F-type epoxy resin, a bisphenol S-type epoxy resin, and 3,3′,5,5′-tetramethyl-4,4′-diglycidyloxydiphenylmethane.

Example of the aralkyl-type epoxy resin include a phenol aralkyl-type epoxy resin, a biphenylaralkyl-type epoxy resin, and a naphthol aralkyl-type epoxy resin.

Examples of other epoxy resins include a stilbene-type epoxy resin, a naphthalene skeleton-containing type epoxy resin, a biphenyl-type epoxy resin, a dihydroanthracene-type epoxy resin, a cyclohexanedimethanol-type epoxy resin, a trimethylol-type epoxy resin, an alicyclic epoxy resin, an aliphatic chain epoxy resin, a heterocyclic epoxy resin, a spiro-ring containing epoxy resin, and a rubber-modified epoxy resin.

((a2) Ethylenically Unsaturated Group-Containing Organic Acid)

The ethylenically unsaturated group-containing organic acid (a2) is preferably an ethylenically unsaturated group-containing monocarboxylic acid.

As examples of the ethylenically unsaturated group of the component (a2), the same examples as of the ethylenically unsaturated group of the component (A) can be mentioned.

Examples of the component (a2) include acrylic acid derivatives, such as acrylic acid, a dimer of an acrylic acid, methacrylic acid, β-furfuryl acrylic acid, β-styryl acrylic acid, cinnamic acid, crotonic acid, and α-cyanocinnamic acid; a semi-ester compound which is a reaction product of a hydroxy group-containing acrylate and a dibasic acid anhydride; and a semi-ester compound which is a reaction product of a vinyl group-containing monoglycidyl ether or a vinyl group-containing monoglycidyl ester and a dibasic acid anhydride.

As the component (a2), one kind may be used alone or two or more kinds may be used in combination.

The semi-ester compound is obtained by reacting one or more ethylenically unsaturated group-containing compound selected from the group consisting of a hydroxy group-containing acrylate, a vinyl group-containing monoglycidyl ether, and a vinyl group-containing monoglycidyl ester with a dibasic acid anhydride. In the reaction, equal moles of the ethylenically unsaturated group-containing compound and the dibasic acid anhydride are preferably reacted.

Examples of the hydroxy group-containing acrylate used for synthesis of the semi-ester compound include hydroxyethyl (meth)acrylate, hydroxypropyl (meth)acrylate, hydroxybutyl (meth)acrylate, polyethylene glycol mono(meth)acrylate, trimethylolpropane di(meth)acrylate, pentaerythritol tri(meth)acrylate, and dipentaerythritol penta(meth)acrylate.

An example of the vinyl group-containing monoglycidyl ether is glycidyl (meth)acrylate.

The dibasic acid anhydride used for synthesis of the semi-ester compound may be one containing a saturated group or one containing an unsaturated group. Example of the dibasic acid anhydride include succinic anhydride, maleic anhydride, tetrahydrophthalic anhydride, phthalic anhydride, methyltetrahydrophthalic anhydride, ethyltetrahydrophthalic anhydride, hexahydrophthalic anhydride, methylhexahydrophthalic anhydride, ethylhexahydrophthalic anhydride, and itaconic anhydride.

In the reaction between the component (a1) and the component (a2), the amount of the component (a2) used relative to 1 equivalent of the epoxy group in the component (a1) is preferably 0.6 to 1.05 equivalents, more preferably 0.7 to 1.02 equivalents, and further preferably 0.8 to 1.0 equivalent. When the component (a1) and the component (a2) are reacted in the above ratio, the photopolymerizability of the component (A) tends to be improved to improve the resolution of vias of the resulting photosensitive resin composition.

The component (a1) and the component (a2) are preferably reacted in a form dissolved in an organic solvent.

Examples of the organic solvent include ketones, such as methyl ethyl ketone and cyclohexanone; aromatic hydrocarbons, such as toluene, xylene, and tetramethylbenzene; glycol ether compounds, such as methylcellosolve, butylcellosolve, methyl carbitol, butyl carbitol, propylene glycol monomethyl ether, dipropylene glycol monoethyl ether, dipropylene glycol diethyl ether, and triethylene glycol monoethyl ether; esters, such as ethyl acetate, butyl acetate, butylcellosolve acetate, and carbitol acetate; aliphatic hydrocarbons, such as octane and decane; and petroleum solvents, such as petroleum ether, petroleum naphtha, hydrogenated petroleum naphtha, and solvent naphtha. As the organic solvent, one kind may be used alone or two or more kinds may be used in combination.

In the reaction between the component (a1) and the component (a2), a catalyst for promoting the reaction is preferably used. Examples of the catalyst include amine-based catalysts, such as triethylamine and benzylmethylamine; quaternary ammonium salt catalysts, such as methyltriethylammonium chloride, benzyltrimethylammonium chloride, benzyltrimethylammonium bromide, and benzyltrimethylammonium iodide; and a phosphine-based catalyst, such as triphenylphosphine. Among them, a phosphine-based catalyst is preferred, and triphenylphosphine is more preferred. As the catalyst, one kind may be used alone or two or more kinds may be used in combination.

When a catalyst is used, the amount of the catalyst used is, from the viewpoint of achieving a moderate reaction rate, relative to 100 parts by mass of the total amount of the component (a1) and the component (a2), preferably 0.01 to 10 parts by mass, more preferably 0.05 to 5 parts by mass, and further preferably 0.1 to 2 parts by mass.

In the reaction between the component (a1) and the component (a2), for the purpose of preventing polymerization in the reaction, a polymerization inhibitor is preferably used. Examples of the polymerization inhibitor include hydroquinone, methylhydroquinone, hydroquinone monomethyl ether, catechol, and pyrogallol. As the polymerization inhibitor, one kind may be used alone or two or more kinds may be used in combination.

When a polymerization inhibitor is used, the amount of the polymerization inhibitor used is, relative to 100 parts by mass of the total amount of the component (a1) and the component (a2), preferably 0.01 to 1 part by mass, more preferably 0.02 to 0.8 parts by mass, and further preferably 0.1 to 0.5 parts by mass.

The temperature in the reaction of the component (a1) and the component (a2) is, from the viewpoint of allowing the reaction to uniformly proceed while achieving a sufficient reactivity, preferably 60 to 150° C., more preferably 80 to 120° C., and further preferably 90 to 110° C.

As described above, the component (A′) obtained by a reaction between the component (a1) and the component (a2) is, when an ethylenically unsaturated group-containing monocarboxylic acid is used as the component (a2), a compound having a hydroxy group formed by a ring-opening addition reaction between the epoxy group of the component (a1) and the carboxy group of the component (a2). Next, by further reacting the component (a3) with the component (A′), an acid-modified vinyl group-containing epoxy resin resulting from semi-esterification of the hydroxy group of the component (A′) (including a hydroxy group that originally exists in the component (a1)) and the acid anhydride group in the component (a3) can be obtained.

((a3) Polybasic Acid Anhydride)

The component (a3) may be one containing a saturated group or one containing an unsaturated group. Examples of the component (a3) include succinic anhydride, maleic anhydride, tetrahydrophthalic anhydride, phthalic anhydride, methyltetrahydrophthalic anhydride, ethyltetrahydrophthalic anhydride, hexahydrophthalic anhydride, methylhexahydrophthalic anhydride, ethylhexahydrophthalic anhydride, and itaconic anhydride. Among them, from the viewpoint of resolution of vias, tetrahydrophthalic anhydride is preferred. As the component (a3), one kind may be used alone or two or more kinds may be used in combination.

In the reaction between the component (A′) and the component (a3), for example, by reacting 0.1 to 1.0 equivalent of the component (a3) relative to 1 equivalent of the hydroxy group in the component (A′), the acid value of an acid-modified vinyl group-containing epoxy resin can be adjusted.

The temperature in the reaction of the component (A′) and the component (a3) is, from the viewpoint of allowing the reaction to uniformly proceed while achieving a sufficient reactivity, preferably 50 to 150° C., more preferably 60 to 120° C., and further preferably 70 to 100° C.

The content of the component (A) in the photosensitive resin composition of this embodiment is not particularly limited, but from the viewpoints of heat resistance, dielectric constant, and chemical resistance, based on the total amount of the resin components in the photosensitive resin composition, is preferably 10 to 80% by mass, more preferably 10 to 60% by mass, further preferably 15 to 45% by mass, particularly preferably 15 to 35% by mass, and most preferably 20 to 35% by mass.

### <(B) Thermosetting Resin>

The component (B) is a thermosetting resin. The component (A) is not encompassed in the component (B).

When the photosensitive resin composition of this embodiment contains the thermosetting resin (B), in addition to improvements in adhesion strength to copper plating and insulation reliability, the heat resistance tends to be improved.

Examples of the thermosetting resin include an epoxy resin, a phenol resin, an unsaturated imide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin. The thermosetting resin is not particularly limited thereto, and a known thermosetting resin can be used. Among them, from the viewpoints of adhesion strength to copper plating, insulation reliability, and heat resistance, an epoxy resin is preferred.

As the component (B), one kind may be used alone or two or more kinds may be used in combination.

The epoxy resin is preferably an epoxy resin having two or more epoxy groups. Epoxy resins are classified into glycidyl ether-type epoxy resins, glycidyl amine-type epoxy resins, and glycidyl ester-type epoxy resins. Among them, a glycidyl ether-type epoxy resin is preferred.

The epoxy resin is also classified into various epoxy resins depending on the difference in the main skeleton, and in the aforementioned epoxy resins of each of type are further classified as follows. Specifically, the epoxy resins are classified into: bisphenol-based epoxy resins, such as a bisphenol A-type epoxy resin, a bisphenol F-type epoxy resin, and a bisphenol S-type epoxy resin; bisphenol-based novolak type epoxy resins, such as a bisphenol A novolak-type epoxy resin and a bisphenol F novolak-type epoxy resin; novolak type epoxy resins other than the aforementioned bisphenol-based novolak-type epoxy resins, such as a phenol novolak-type epoxy resin, a cresol novolak-type epoxy resin, and a biphenyl novolak-type epoxy resin; phenol aralkyl-type epoxy resins; stilbene-type epoxy resins; naphthalene skeleton-containing epoxy resins, such as a naphthol novolak-type epoxy resin, a naphthol-type epoxy resin, a naphthol aralkyl-type epoxy resin, and a naphthylene ether-type epoxy resin; biphenyl-type epoxy resins; biphenyl aralkyl-type epoxy resins; xylylene-type epoxy resins; dihydroanthracene-type epoxy resins; alicyclic epoxy resins, such as a saturated dicyclopentadiene-type epoxy resin; heterocyclic epoxy resins; spiro ring-containing epoxy resins; cyclohexanedimethanol-type epoxy resins; trimethylol-type epoxy resins; aliphatic chain epoxy resins; rubber-modified epoxy resins; and the like.

Among them, in particular, from the viewpoints of heat resistance, electrical insulation reliability, developability, and adhesion strength to copper plating, the epoxy resin preferably contains at least one selected from the group consisting of a bisphenol-based epoxy resin, a naphthalene skeleton-containing epoxy resin, and a biphenylaralkyl-type epoxy resin, and more preferably contains at least one selected from the group consisting of a naphthalene skeleton-containing epoxy resin and a biphenylaralkyl-type epoxy resin.

The equivalent ratio of the epoxy group of the component (B) to the acidic substituent of the component (A) [epoxy group/acidic substituent] in the photosensitive resin composition of this embodiment is not particularly limited, but from the viewpoints of insulation reliability, dielectric constant, heat resistance, and adhesion strength to copper plating, is preferably 0.5 to 6.0, more preferably 0.7 to 4.0, further preferably 0.8 to 2.0, and particularly preferably 0.9 to 1.8.

The content of the component (B) in the photosensitive resin composition of this embodiment is not particularly limited, but from the viewpoints of insulation reliability, dielectric constant, heat resistance, and adhesion strength to copper plating, based on the total amount of the resin components in the photosensitive resin composition, is preferably 1 to 50% by mass, more preferably 5 to 30% by mass, and further preferably 10 to 25% by mass.

### <(C) Crosslinking Agent>

The photosensitive resin composition of this embodiment preferably further contains a crosslinking agent as a component (C). The crosslinking agent is preferably a crosslinking agent that has two or more ethylenically unsaturated groups and has no acidic substituent. The crosslinking agent increases the crosslink density after curing of a photosensitive resin film by reacting with the ethylenically unsaturated group of the component (A). Accordingly, when the photosensitive resin composition of this embodiment contains a crosslinking agent, the heat resistance and the dielectric constant tend to be furthermore improved.

As the component (C), one kind may be used alone or two or more kinds may be used in combination.

Examples of the component (C) include a bifunctional monomer which has two ethylenically unsaturated groups and a polyfunctional monomer which has three or more ethylenically unsaturated groups. The component (C) preferably contains the polyfunctional monomer.

As the ethylenically unsaturated group of the component (C), the same examples as for the ethylenically unsaturated group of the component (A) are mentioned, and preferred examples are also the same.

Examples of the bifunctional monomer include aliphatic di(meth)acrylate, such as trimethylolpropane di(meth)acrylate, polypropylene glycol di(meth)acrylate, and polyethylene glycol di(meth)acrylate; di(meth)acrylates having an alicyclic skeleton, such as dicyclopentadiene di(meth)acrylate and tricyclodecane dimethanol di(meth)acrylate; and aromatic di(meth)acrylates, such as 2,2-bis(4-(meth)acryloxypolyethoxypolypropoxyphenyl)propane and bisphenol A diglycidyl ether di(meth)acrylate.

Among them, from the viewpoint of achieving lower dielectric constant, a di(meth)acrylate having an alicyclic skeleton is preferred, and tricyclodecane dimethanol diacrylate is more preferred.

As the polyfunctional monomer, a (meth)acrylate compound having a trimethylolpropane-derived skeleton, such as trimethylolpropane tri(meth)acrylate; (meth)acrylate compounds having a tetramethylolmethane-derived skeleton, such as tetramethylolmethane tri(meth)acrylate and tetramethylolmethane tetra(meth)acrylate; (meth)acrylate compounds having a pentaerythritol-derived skeleton, such as pentaerythritol tri(meth)acrylate and pentaerythritol tetra(meth)acrylate; (meth)acrylate compounds having a dipentaerythritol-derived skeleton, such as dipentaerythritol penta(meth)acrylate and dipentaerythritol hexa(meth)acrylate; a (meth)acrylate compound having a ditrimethylolpropane-derived skeleton, such as ditrimethylolpropane tetra(meth)acrylate; and a (meth)acrylate compound having a diglycerin-derived skeleton. Among them, from the viewpoints of resolution of vias and adhesion strength to copper plating, a (meth)acrylate compound having a trimethylolpropane-derived skeleton is preferred, and trimethylolpropane tri(meth)acrylate is more preferred.

Here, the “(meth)acrylate compound having an XXX-derived skeleton” (in which XXX is a compound name) means an esterification product of XXX and (meth)acrylic acid, and the esterification product encompasses a compound modified with an alkyleneoxy group.

When the photosensitive resin composition of this embodiment contains the crosslinking agent (C), the content of the crosslinking agent (C) is not particularly limited, but from the viewpoints of heat resistance and dielectric constant, relative to 100 parts by mass of the component (A), is preferably 10 to 85 parts by mass, more preferably 25 to 80 parts by mass, further preferably 35 to 75 parts by mass, and particularly preferably 35 to 60 parts by mass.

### <(D) Elastomer>

The photosensitive resin composition of this embodiment preferably further contains an elastomer as a component (D). When the photosensitive resin composition of this embodiment contains the elastomer (D), the adhesion strength to copper plating tends to be furthermore improved. In addition, when the photosensitive resin composition of this embodiment contains the elastomer (D), a suppressing effect on the “reduction in flexibility and adhesion strength to copper plating” which is attributable to strain (internal stress) which possibly occurs due to curing shrinkage of the component (A) tends to be obtained.

As the elastomer (D), one kind may be used alone or two or more kinds may be used in combination.

The elastomer (D) may have a reactive functional group at a molecular terminal or in a molecular chain.

Examples of the reactive functional group include an acid anhydride group, an epoxy group, a hydroxy group, a carboxy group, an amino group, an amide group, an isocyanato group, an acryl group, a methacryl group, and a vinyl group. Among them, from the viewpoints of resolution of vias and adhesion strength to copper plating, an acid anhydride group, an epoxy group, a hydroxy group, a carboxy group, an amino group, and an amide group are preferred, an acid anhydride group and an epoxy group are more preferred, and an acid anhydride group is further preferred.

The acid anhydride group is preferably an acid anhydride group derived from phthalic anhydride, maleic anhydride, trimellitic anhydride, pyromellitic anhydride, hexahydrophthalic anhydride, tetrahydrophthalic anhydride, methylnadic anhydride, nadic anhydride, glutaric anhydride, dimethylglutaric anhydride, diethylglutaric anhydride, succinic anhydride, methylhexahydrophthalic anhydride, methyltetrahydrophthalic anhydride, and the like, and more preferably an acid anhydride group derived from maleic anhydride.

When the elastomer (D) has an acid anhydride group, from the viewpoints of resolution of vias and dielectric constant, the number of the acid anhydride groups in one molecule is preferably 1 to 10, more preferably 3 to 10, and further preferably 6 to 10.

The photosensitive resin composition of this embodiment preferably contains, as the elastomer (D), an elastomer having an ethylenically unsaturated group and an acidic substituent.

As examples of the acidic substituent and the ethylenically unsaturated group, the same examples as for the acidic substituent and ethylenically unsaturated group of the component (A) are mentioned. Among them, the elastomer (D) is preferably one that has the aforementioned acid anhydride group as the acidic substituent and has a 1,2-vinyl group to be described later as the ethylenically unsaturated group.

Examples of the elastomer (D) include a polybutadiene-based elastomer, a polyester-based elastomer, a styrene-based elastomer, an olefin-based elastomer, a urethane-based elastomer, a polyamide-based elastomer, an acryl-based elastomer, a silicone-based elastomer, and derivatives of these elastomers. Among them, from the viewpoints of an improvement in adhesion strength to copper plating and improvements in compatibility with a resin component and solubility, a polybutadiene-based elastomer is preferred.

A suitable example of the polybutadiene-based elastomer is one that contains a 1,2 -vinyl group and has a structural unit of the 1,4-trans isomer and a structural unit of the 1,4-cis isomer.

As described above, from the viewpoint of resolution of vias, the polybutadiene-based elastomer is preferably a polybutadiene-based elastomer having an acid anhydride group, which is modified with an acid anhydride, and is more preferably a polybutadiene-based elastomer having an acid anhydride group that is derived from maleic anhydride.

The polybutadiene-based elastomer is available as a commercial product, and specific examples thereof include “POLYVEST (registered tradename) MA75” and “POLYVEST (registered tradename) EP MA120” (tradenames, both manufactured by Evonik Industries), and “Ricon (registered tradename) 100”, “Ricon (registered tradename) 130MA8”, “Ricon (registered tradename) 131MA5”, “Ricon (registered tradename) 131MA17”, and “Ricon (registered tradename) 184MA6” (tradenames, all manufactured by Cray Valley).

From the viewpoint of adhesion strength to copper plating, the polybutadiene-based elastomer may be a polybutadiene having an epoxy group [hereinafter sometimes referred to as epoxidated polybutadiene].

The epoxidated polybutadiene is preferably an epoxidated polybutadiene represented by the following general formula (D-1) from the viewpoints of adhesion strength to copper plating and softness.

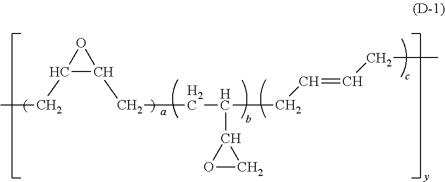

(In the formula, a, b, and c each represent the ratio of the structural unit in the parentheses, and a is 0.05 to 0.40, b is 0.02 to 0.30, and c is 0.30 to 0.80, and further satisfy a+b+c=1.00 and (a+c)>b, and y represents the number of the structural unit in the brackets and is an integer of 10 to 250.)

In the general formula (D-1), the bonding order of the structural units in the brackets is not defined. That is, the structural unit shown in the left side, the structural unit shown in the center, and the structural unit shown in the right side may be exchanged. When the structural units are expressed as (a), (b), and (c), respectively, various bonding orders, such as -[(a)-(b)-(c)]-[(a)-(b)-(c)-]-, -[(a)-(c)-(b)]-[(a)-(c)-(b)-]-, -[(b)-(a)-(c)]-[(b)-(a)-(c)-]-, -[(a)-(b)-(c)]-[(c)-(b)-(a)-]-, -[(a)-(b)-(a)]-[(c)-(b)-(c)-]-, -[(c)-(b)-(c)]-[(b)-(a)-(a)-]-, are possible.

From the viewpoints of adhesion strength to copper plating and softness, a is preferably 0.10 to 0.30, b is preferably 0.10 to 0.30, and cis preferably 0.40 to 0.80. From the same point of view, y is preferably an integer of 30 to 180.

An example of the polyester-based elastomer is one obtained by polycondensation of a dicarboxylic acid or a derivative thereof and a diol compound or a derivative thereof.

Examples of the dicarboxylic acid include aromatic dicarboxylic acids, such as terephthalic acid, isophthalic acid, and naphthalene dicarboxylic acid and aromatic dicarboxylic acids obtained by substituting a hydrogen atom in the aromatic nuclear thereof with a methyl group, an ethyl group, a phenyl group, or the like; aliphatic dicarboxylic acids having 2 to 20 carbon atoms, such as adipic acid, sebacic acid, and dodecanedicarboxylic acid; and an alicyclic dicarboxylic acid, such as cyclohexanedicarboxylic acid.

Examples of the diol compound include aliphatic diols, such as ethylene glycol, 1,3-propanediol, 1,4-butanediol, 1,6-hexanediol, and 1,10-decanediol; an alicyclic diol, such as 1,4-cyclohexanediol; and aromatic diols, such as bisphenol A, bis(4-hydroxyphenyl)methane, bis(4-hydroxy-3-methylphenyl)propane, and resorcin.

In addition, a suitable example of the polyester-based elastomer is a multiblock copolymer containing an aromatic polyester (for example, polybutylene terephthalate) part as a hard segment component and an aliphatic polyester (for example, polytetramethylene glycol) part as a soft segment component. The multiblock copolymer has various grades depending on the difference in the types, ratio, and molecular weights of the hard segment and the soft segment.

The number average molecular weight of the elastomer (D) is not particularly limited, but is preferably 10,000 to 80,000, and may be 20,000 to 70,000, may be 30,000 to 65,000, or may be 40,000 to 60,000. The number average molecular weight of the elastomer (D) can be determined by calculation based on standard polystyrenes according to gel permeation chromatography (GPC) using tetrahydrofuran as a solvent.

When the photosensitive resin composition of this embodiment contains the elastomer (D), the content of the elastomer (D) is not particularly limited, but from the viewpoints of heat resistance and adhesion strength to copper plating, based on the total amount of the resin components in the photosensitive resin composition, is preferably 0.5 to 15% by mass, more preferably 1 to 10% by mass, further preferably 1 to 8% by mass, and particularly preferably 3 to 8% by mass.

### <(E) Organic Filler>

The photosensitive resin composition of this embodiment may further contain an organic filler as a component (E). When the photosensitive resin composition of this embodiment contains the organic filler (E), the photosensitive resin composition and the photosensitive resin film tend to have a low specific gravity, and depending on the material, the dielectric constant tends to furthermore decrease.

The component (E) preferably contains resin particles formed of at least one selected from the group consisting of a resin having a fluorine atom, polyethylene, polypropylene, polystyrene, polyphenylene ether, and a silicone. Among them, from the viewpoint of the decreasing effect on the dielectric constant, the component (E) preferably contains resin particles formed of a resin having a fluorine atom, and more preferably contains resin particles formed of a polytetrafluoroethylene (PTFE) resin.

The volume average particle size of the resin particles is not particularly limited, but is preferably 20 to 1,000 nm, more preferably 30 to 800 nm, further preferably 50 to 500 nm, and particularly preferably 100 to 300 nm. The measurement method of the volume average particle size is as described above.

When the photosensitive resin composition of this embodiment contains the organic filler (E), the content of the organic filler (E) is not particularly limited, but, based on the total amount of the resin components in the photosensitive resin composition, is preferably 1 to 45% by mass, more preferably 3 to 40% by mass, further preferably 5 to 30% by mass, and particularly preferably 10 to 30% by mass. When the content of the organic filler (E) based on the total amount of the resin components in the photosensitive resin composition is the lower limit or more, there is a tendency that the dielectric constant can be furthermore decreased, and when the content is the upper limit or less, there is a tendency that a decrease in the adhesion strength to copper plating can be suppressed. From the same point of view, in particular, the content of the resin having a fluorine atom based on the total amount of the resin components in the photosensitive resin composition is preferably 1 to 45% by mass, more preferably 3 to 40% by mass, further preferably 5 to 30% by mass, and particularly preferably 10 to 30% by mass.

In particular, when the organic filler (E) contains resin particles formed of a resin having a fluorine atom, the total amount of the component (X) and the component (E) is, from the viewpoint of adhesion strength to copper plating, based on the total amount of the resin components in the photosensitive resin composition, preferably 50% by volume or less, more preferably 45% by volume or less, and further preferably 40% by volume or less. The lower limit of the total amount of the component (X) and the component (E) is not particularly limited, but from the viewpoint of decreasing dielectric constant, is preferably 2% by volume or more, more preferably 10% by volume or more, further preferably 20% by volume or more, and particularly preferably 30% by volume or more.

### <(F) Curing Agent>

The photosensitive resin composition of this embodiment preferably contains a curing agent as a component (F). When the photosensitive resin composition of this embodiment contains the curing agent (F), there is a tendency that the heat resistance, the dielectric constant, and the like can be furthermore improved.

As the curing agent (F), one kind may be used alone or two or more kinds may be used in combination.

As the curing agent (F), a curing agent for the thermosetting resin (B) can be used. For example, when the thermosetting resin (B) is an epoxy resin, an epoxy resin curing agent is preferably used. Examples of the epoxy resin curing agent include guanamines, such as acetoguanamine and benzoguanamine; polyamines, such as diaminodiphenylmethane, m-phenylenediamine, m-xylylenediamine, diaminodiphenyl sulfone, dicyandiamide, urea, a urea derivative, melamine, and polybasic hydrazide; organic acid salts and/or epoxy adducts thereof; an amine complex of boron trifluoride; triazine derivatives, such as ethyldiamino-S-triazine, 2,4-diamino-S-triazine, and 2,4-diamino-6-xylyl-S-triazine; and polyphenols, such as polyvinyl phenol, polyvinyl phenol bromide, phenol novolak, alkylphenol novolak, and a triazine ring-containing phenol novolak resin.

The polyphenol may be, for example, a modified polyphenol which is modified with melamine, benzoguanamine, or the like. The hydroxy group equivalent of the polyphenol is not particularly limited, but is preferably 40 to 300 g/eq, and may be 40 to 250 g/eq, may be 60 to 200 g/eq, may be 80 to 160 g/eq, or may be 100 to 140 g/eq. Here, the hydroxy group equivalent (g/eq) can be determined by titration according to an acetylation method with acetic anhydride.

When the photosensitive resin composition of this embodiment contains the curing agent (F), the content of the curing agent (F) is not particularly limited, but from the viewpoint of furthermore improving heat resistance and dielectric constant, based on the total amount of the resin components in the photosensitive resin composition, is preferably 0.01 to 10% by mass, more preferably 0.05 to 5% by mass, and further preferably 0.1 to 1% by mass.

### <(G) Curing Accelerator>

The photosensitive resin composition of this embodiment preferably further contains a curing accelerator as a component (G). When the photosensitive resin composition of this embodiment contains the curing accelerator (G), there is a tendency that the heat resistance, dielectric constant, and the like can be furthermore improved.

As the curing accelerator (G), one kind may be used alone or two or more kinds may be used in combination.

Examples of the curing accelerator (G) include imidazole-based compounds, such as 2-methylimidazole, 2-ethyl-4-methylimidazole, 1-benzyl-2-methylimidazole, 2-phenylimidazole, 2-phenyl-1-benzyl-1H-imidazole, 2-phenyl-4-methyl-5-hydroxymethylimidazole, and isocyanate-masked imidazole (addition reaction product of a hexamethylene diisocyanate resin and 2-ethyl-4-methylimidazole); tertiary amines, such as trimethylamine, N,N-dimethyloctylamine, N-benzyldimethylamine, pyridine, N-methylmorpholine, hexa(N-methyl)melamine, 2,4,6-tris(dimethylaminophenol), tetramethylguanidine, and m-aminophenol; organic phosphines, such as tributylphosphine, triphenylphosphine, and tris-2-cyanoethylphosphine; phosphonium salts, such as tri-n-butyl(2,5-dihydroxyphenyl)phosphonium bromide and hexadecyltributylphosphonium chloride; quaternary ammonium salts, such as benzyltrimethylammonium chloride and phenyltributylammonium chloride; polybasic acid anhydrides as described above; diphenyliodonium tetrafluoroborate, triphenylsulfonium hexafluoroantimonate, and 2,4,6-triphenylthiopyrylium hexafluorophosphate.

Among them, from the viewpoint of achieving a superior curing action, an imidazole-based compound is preferred.

When the photosensitive resin composition of this embodiment contains the curing accelerator (G), the content of the curing accelerator (G) is not particularly limited, but from the viewpoint of furthermore improving the heat resistance and dielectric constant, based on the total amount of the resin components in the photosensitive resin composition, is preferably 0.01 to 10% by mass, more preferably 0.05 to 5% by mass, and further preferably 0.1 to 2% by mass.

### <(H) Photopolymerization Initiator>

The photosensitive resin composition of this embodiment preferably further contains a photopolymerization initiator as a component (H). When the photosensitive resin composition of this embodiment contains the photopolymerization initiator (H), the resolution of vias tends to be furthermore improved.

As the photopolymerization initiator (H), one kind may be used alone or two or more kinds may be used in combination. From the viewpoint of resolution of vias, the photosensitive resin composition of this embodiment preferably contains two or more kinds of the component (H).

The photopolymerization initiator (H) is not particularly limited as long as it is able to photopolymerize ethylenically unsaturated groups, and can be appropriately selected from generally used photopolymerization initiators.

Examples of the photopolymerization initiator (H) include benzoin-based compounds, such as benzoin, benzoin methyl ether, and benzoin isopropyl ether; acetophenone-based compounds, such as acetophenone, 2,2-dimethoxy-2-phenylacetophenone, 2,2-diethoxy-2-phenylacetophenone, 1,1-dichloroacetophenone, 1-hydroxycyclohexyl phenyl ketone, 2-benzyl-2-dimethylamino-1-(4-morpholinophenyl)-1-butanone, 2-[4-(methylthio)benzoyl]-2-(4-morpholinyl)propanone, and N,N-dimethylaminoacetophenone; anthraquinone-based compounds, such as 2-methylanthraquinone, 2-ethylanthraquinone, 2-tert-butylanthraquinone, 1-chloroanthraquinone, 2-amylanthraquinone, and 2-aminoanthraquinone; ketal-based compounds, such as acetophenone dimethyl ketal and benzyl dimethyl ketal; acridine-based compounds, such as 9-phenylacridine and 1,7-bis(9,9′-acridinyl)heptane; an acylphosphine oxide-based compound, such as bis(2,4,6-trimethylbenzoyl)phenylphosphine oxide; and oxime ester-based compounds, such as 1,2-octanedione-1-[4-(phenylthio)phenyl]-2-(O-benzoyloxime), 1-[9-ethyl-6-(2-methylbenzoyl)-9H-carbazol-3-yl]ethanone 1-(0-acetyloxime), and 1-phenyl-1,2-propanedione-2-[0-ethoxycarbonyl]oxime].

Among them, an oxime ester-based compound and an acylphosphine oxide-based compound are preferred, and 1-[9-ethyl-6-(2-methylbenzoyl)-9H-carbazol-3-yl]ethanone 1-(0-acetyloxime) and bis(2,4,6-trimethylbenzoyl)phenylphosphine oxide are more preferred. An oxime ester-based compound has an advantage in that it improves photocurability, and an acylphosphine oxide-based compound has an advantage in that it improves the curing degree of the bottom of a cured product obtained by curing a photosensitive resin film to suppress undercut. When an oxime ester-based compound and an acylphosphine oxide-based compound are used in combination, the resolution of vias tends to be furthermore improved.

When the photosensitive resin composition of this embodiment contains the photopolymerization initiator (H), the content of the photopolymerization initiator (H) is not particularly limited, but, based on the total amount of the resin components in the photosensitive resin composition, is preferably 0.01 to 20% by mass, more preferably 0.05 to 10% by mass, further preferably 0.05 to 3% by mass, and particularly preferably 0.05 to 1.0% by mass. When the content of the photopolymerization initiator (H) is the lower limit or more, there is a tendency that elution of an exposed portion in development can be reduced, and when the content is the upper limit or less, there is a tendency that heat resistance is increased.

### <(I) Photosensitizer>

The photosensitive resin composition of this embodiment may contain a photosensitizer as a component (I) as required.

As the photosensitizer (I), one kind may be used alone or two or more kinds may be used in combination. From the viewpoint of resolution of vias, the photosensitive resin composition of this embodiment may contain two or more kinds of the component (I).

Examples of the photosensitizer (I) include thioxanthone-based compounds, such as 2,4-dimethylthioxanthone, 2,4-diethylthioxanthone, 2-chlorothioxanthone, and 2,4-diisopropylthioxanthone; tertiary amines, such as trialkylamine and triethanolamine; dialkylaminobenzoic acid alkyl esters, such as ethyl N,N-dimethylaminobenzoate and amyl N,N-dimethylaminobenzoate; bis(dialkylamino)benzophenones, such as 4,4′-bis(dimethylamino)benzophenone and 4,4′-bis(diethylamino)benzophenone; a phosphine-based compound, such as triphenylphosphine; a toluidine-based compound, such as N,N-dimethyltoluidine; anthracene-based compounds, such as 9,10-dimethoxyanthracene, 2-ethyl-9,10-dimethoxyanthracene, and 2-ethyl-9,10-diethoxyanthracene; a perylene-based compound; and a coumarin-based compound.

From the viewpoints of resolution of vias and improvement of the shape of vias, the photosensitizer (I) is preferably bis(dialkylamino)benzophenone, and more preferably 4,4′-bis(diethylamino)benzophenone.

When the photosensitive resin composition of this embodiment contains the photosensitizer (I), the content of the photosensitizer (I) is not particularly limited, but based on the total amount of the resin components in the photosensitive resin composition, is preferably 0.01 to 5% by mass, more preferably 0.05 to 3% by mass, further preferably 0.1 to 1.5% by mass, and particularly preferably 0.1 to 1.0% by mass. When the content of the photosensitizer (I) is the lower limit or more, the curing degree of the bottom of a curing product obtained by curing a photosensitive resin film tends to sufficiently increase, and when the content is the upper limit or less, the curing degree of the bottom of a cured product tends to be moderately low.

### <(J) Additives>

The photosensitive resin composition of this embodiment may contain various commonly known additives, as required, for example, an inorganic filler other than the component (X); pigments, such as phthalocyanine blue, phthalocyanine green, iodine green, diazo yellow, crystal violet, titanium oxide, carbon black, and naphthalene black; an adhesive assistant, such as melamine; a foam stabilizer, such as a silicone compound; a polymerization inhibitor; a thickener; and a flame retardant.

The content of the additive (J) may be appropriately adjusted according to each purpose, and the content of each additive based on the total amount of the resin components in the photosensitive resin composition is preferably 0.01 to 5% by mass, and may be 0.05 to 3% by mass, or may be 0.1 to 1% by mass.

### <Diluent>

The photosensitive resin composition of this embodiment may contain a diluent as required. As the diluent, an organic solvent or the like can be used. Examples of the organic solvent include ketones, such as methyl ethyl ketone and cyclohexanone; aromatic hydrocarbons, such as toluene, xylylene, and tetramethylbenzene; glycol ether-based compounds, such as methylcellosolve, butylcellosolve, methylcarbitol, butylcarbitol, propylene glycol monomethyl ether, dipropylene glycol monoethyl ether, dipropylene glycol diethyl ether, and triethylene glycol monoethyl ether; esters, such as ethyl acetate, butyl acetate, propylene glycol monoethyl ether acetate, butylcellosolve acetate, and carbitol acetate; aliphatic hydrocarbons, such as octane and decane; and petroleum solvents, such as petroleum ether, petroleum naphtha, hydrogenated petroleum naphtha, and solvent naphtha. As the diluent, one kind may be used alone or two or more kinds may be used in combination.

When the photosensitive resin composition of this embodiment contains the diluent, the content of the diluent can be appropriately selected for the purpose of adjusting the concentration of the total amount of solid components in the photosensitive resin composition within preferably 40 to 90% by mass, more preferably 50 to 85% by mass, and further preferably 60 to 80% by mass. By adjusting the amount of the diluent used within the above range, the applicability of the photosensitive resin composition is improved, making it possible to form a finer pattern.

The photosensitive resin composition of this embodiment can be obtained by kneading and mixing the components with a roll mill, a bead mill, or the like.

Here, the photosensitive resin composition of this embodiment may be used in a liquid state (liquid form) or may be used in a film state (film form).

When used in a liquid form, the method for applying the photosensitive resin composition of this embodiment is not particularly limited. Examples of the method include various application methods, such as a printing method, a spin coating method, a spray coating method, a jet dispensing method, an inkjet method, and a dip coating method. Among them, from the viewpoint of further easily forming a photosensitive layer, a printing method and a spin coating method are preferred.

When the photosensitive resin composition is used in a film form, the photosensitive resin composition can be used, for example, in a form of a photosensitive resin film to be described later. In this case, by laminating it on a carrier film using a laminator or the like, a photosensitive layer of a desired thickness can be formed. Use of the photosensitive resin composition in a film form is more preferred since the production efficiency of a multilayered printed wiring board is then increased.

Since the photosensitive resin composition of this embodiment is suited to via formation by photolithography (also referred to as photo-via formation), the present disclosure also provides a photosensitive resin composition for photo-via formation formed of the photosensitive resin composition of this embodiment.

### [Photosensitive Resin Film]

The photosensitive resin film of this embodiment is formed by using the photosensitive resin composition of this embodiment. The photosensitive resin film is useful as a photosensitive layer for forming an interlayer insulating layer.

An aspect in which the photosensitive resin film of this embodiment is provided on a carrier film can be adopted.

The photosensitive resin film of this embodiment can be formed, for example, by applying the photosensitive resin composition of this embodiment on a carrier film with a known application apparatus, such as a comma coater, a bar coater, a kiss coater, a roll coater, a gravure coater, or a die coater, and drying.

Examples of the carrier film include polyesters, such as polyethylene terephthalate and polybutylene terephthalate; and polyolefins, such as polypropylene and polyethylene. The thickness of the carrier film is preferably 5 to 100 μm, more preferably 10 to 60 μm, and further preferably 15 to 45 μm.

On the photosensitive resin film of this embodiment, a protective film can be provided on a surface opposite to the surface in contact with the carrier film. As the protective film, a polymer film, such as polyethylene or polypropylene, or the like can be used. The same polymer film as the aforementioned carrier film may be used or a different polymer film may be used.

A coating film formed by applying the photosensitive resin composition can be dried by using, for example, a drier by means of hot air drying, far infrared radiation, or near infrared radiation. The drying temperature is preferably 60 to 150° C., more preferably 70 to 120° C., and further preferably 80 to 110° C. The drying time is preferably 1 to 60 minutes, more preferably 2 to 30 minutes, and further preferably 5 to 20 minutes. The content of the residual diluent in the photosensitive resin film after drying is, from the viewpoint of avoiding diffusion of the diluent in a production process of a multilayered printed wiring board, preferably 3% by mass or less, more preferably 2% by mass or less, and further preferably 1% by mass or less.

The thickness of the photosensitive resin film (photosensitive layer) (the thickness after drying) is not particularly limited, but from the viewpoint of reducing the thickness of a multilayered printed wiring board, is preferably 1 to 100 μm, more preferably 3 to 50 μm, and further preferably 5 to 40 μm.

The photosensitive resin film of this embodiment is superior in the resolution of vias and the adhesion strength to copper plating, and thus, is suited to an interlayer insulating layer of a multilayered printed wiring board.

### [Multilayered Printed Wiring Board and Production Method Thereof]

The multilayered printed wiring board of this embodiment contains an interlayer insulating layer formed by using the photosensitive resin composition of this embodiment or the photosensitive resin film of this embodiment. Here, the expression “contains an interlayer insulating layer” encompasses a case of containing an interlayer insulating layer as it is and a case of containing an interlayer insulating layer in a state after, for example, a processing, such as via formation, a treatment of various types such as roughening treatment, wiring formation, or the like is applied.

A production method of the multilayered printed wiring board of this embodiment is not particularly limited as long as it includes a step of forming an interlayer insulating layer by using the photosensitive resin composition or the photosensitive resin film of this embodiment. For example, the multilayered printed wiring board can be further easily produced by the method for producing a multilayered printed wiring board of this embodiment.

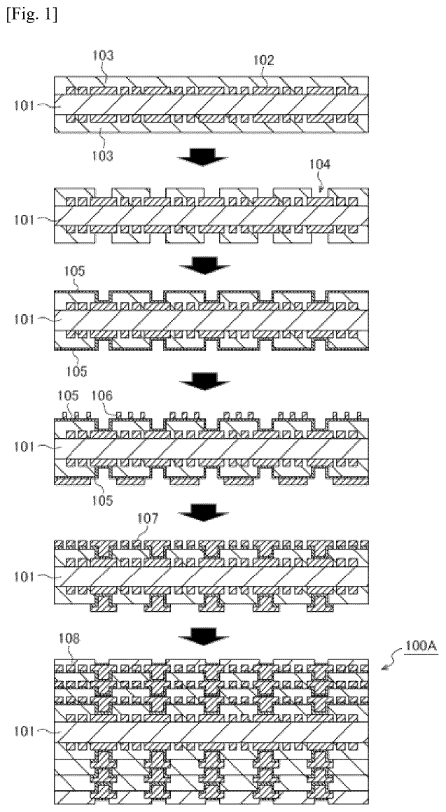

The method for producing a multilayered printed wiring board using the photosensitive resin film of this embodiment will be described appropriately with reference to FIG. 1.

A multilayered printed wiring board 100A can be produced, for example, by a production method including the following (1) to (4) [however, (3) is an option].
(1): laminating the photosensitive resin film of this embodiment on one surface or both surfaces of a circuit substrate (hereinafter referred to as a “lamination step (1)”).
(2): exposing and developing the photosensitive resin film laminated in the step (1) to form an interlayer insulating layer having a via (hereinafter referred to as a “photo-via formation step (2)”).
(3): subjecting the via and the interlayer insulating layer to a roughening treatment (hereinafter referred to as a “roughening treatment step (3)”).
(4): forming a circuit pattern on the interlayer insulating layer (hereinafter referred to as a “circuit pattern formation step (4)”).

In the present description, as described above, a given operation may be referred to as an “XX step” for convenience, but the XX step is not limited only to the aspect specifically described in the present description.

### (Lamination Step (1))

The lamination step (1) is a step of laminating the photosensitive resin film of this embodiment on one surface or both surfaces of a circuit substrate (a substrate 101 having a circuit pattern 102) by using a vacuum laminator. Examples of the vacuum laminator include a vacuum applicator manufactured by Nichigo-Morton Co., Ltd., a vacuum pressure type laminator manufactured by Meiki Co., Ltd., a roll type dry coater manufactured by Hitachi, Ltd., and a vacuum laminator manufactured by Showa Denko Materials Electronics Co., Ltd.

In the case where a protective film is provided on the photosensitive resin film, after stripping or removing the protective film, the photosensitive resin film can be laminated by pressure bonding the photosensitive resin film to the circuit substrate while pressurizing and heating the photosensitive resin film and the circuit substrate in a state of the photosensitive resin film being in contact with the circuit substrate.

The lamination can be carried out, for example, at a pressure bonding temperature of 70 to 130° C. and a pressure bonding pressure of 0.1 to 1.0 MPa under a reduced pressure of an air pressure of 20 mmHg (26.7 hPa) or less optionally after preliminarily heating the photosensitive resin film and the circuit substrate. However, the conditions are not particularly limited to these conditions. The lamination method may be in a batch mode or may be in a continuous mode with rolls.

Finally, the photosensitive resin film laminated on the circuit substrate is cooled to around room temperature to thereby form an interlayer insulating layer 103. When the photosensitive resin film has a carrier film, the carrier film may be stripped off here or may be stripped off after exposure as described later.

### (Photo-Via Formation Step (2))

In the photo via formation step (2), at least a part of the photosensitive resin film laminated on the circuit substrate is exposed, followed by performing development. The portion irradiated with active rays is photo-cured through the exposure to form a pattern. The exposure method is not particularly limited, and for example, a method of irradiating the photosensitive resin film with active rays imagewise via, i. e., through a negative or positive mask pattern that is called an artwork (mask exposure method) may be adopted, or a method of irradiating the photosensitive resin film with active rays imagewise by a direct drawing exposure method, such as an LDI (laser direct imaging) exposure method and a DLP (digital light processing) exposure method, may be adopted.

As a light source of the active rays, a known light source can be used. Specifically, examples of the light source include: gas lasers, such as a carbon arc lamp, a mercury vapor arc lamp, a high-pressure mercury lamp, a xenon lamp, and an argon laser; a solid laser, such as a YAG laser; and one that effectively radiates ultraviolet rays or visible light rays, such as a semiconductor laser. Although the exposure amount is appropriately selected depending upon the light source used, the thickness of the photosensitive layer, or the like, for example in the case of irradiation with ultraviolet rays from a high-pressure mercury lamp and a thickness of the photosensitive layer of 1 to 100 μm, the exposure amount is typically preferably about 10 to 1,000 mJ/cm², more preferably 50 to 700 mJ/cm², further preferably 150 to 550 mJ/cm², and particularly preferably 250 to 500 mJ/cm².

In the development, an uncured portion of the photosensitive layer is removed from the top of the substrate, whereby a photo-cured portion is formed, as an interlayer insulating layer, on the substrate.

In the case where the carrier film exists on the photosensitive layer, after removing the carrier film, the removal (development) of the unexposed portion is performed. Development methods are divided into wet development and dry development and either of them may be adopted. However, the wet development is widely adopted, and also in this embodiment, the wet development can be adopted.

In the case of wet development, the development is performed by a known development method with a developer corresponding to the photosensitive resin composition. Examples of the development method include a dip method, a puddle method, a spray method, blushing, slapping, scrapping, and agitation immersion. Among them, from the viewpoint of improving the resolution of vias, the spray method is preferred, and a high-pressure spray method is more preferred as the spray method. The development may be carried out by a single method or may be carried out by a combination of two or more methods.

The constitution of the developer is appropriately selected according to the constitution of the photosensitive resin composition. Examples of the developer include an alkaline aqueous solution, an aqueous developer, and an organic solvent-based developer. Among them, an alkaline aqueous solution is preferred.

In the photo via formation step (2), after performing the exposure and the development, by optionally performing post UV curing with an exposure amount of about 0.2 to 10 J/cm² (preferably 0.5 to 5 J/cm²) and post thermal curing at a temperature of about 60 to 250° C. (preferably 120 to 200° C.), the interlayer insulating layer may be, and is preferably, further cured.

According to the above method, an interlayer insulating layer having a via 104 is formed. The shape of the via is not particularly limited, and when it is described in terms of a cross-sectional shape, examples thereof include a quadrilateral and a reverse trapezoid (the top side is longer than the bottom side). When the shape of the via is described in terms of a shape seen from the front (direction in which the via bottom is seen), examples thereof include a circle and a quadrilateral. In the formation of a via by photolithography in this embodiment, a via having a cross-sectional shape of a reverse trapezoid (the top side is longer than the bottom side) can be formed, and in this case, the coating property on the via wall surface in copper plating is improved, which is preferable.

The size (diameter) of the via 104 formed by this step can be less than 40 μm, and the size can also be 35 μm or less, or 30 μm or less. The size can be smaller than that of a via prepared by laser processing. The lower limit of the size (diameter) of the via formed by this step is not particularly limited, but it may be 15 μm or more, or may be 20 μm or more.

However, the size (diameter) of the via 104 formed by this step is not always limited to less than 40 μm, and, for example, may be arbitrarily selected within the range of 15 to 300 μm.

### (Roughening Treatment Step (3))

As required, as the roughening treatment step (3), the via and the surface of the interlayer insulating layer are subjected to a roughening treatment with a roughening liquid. Note that in the case where a smear is generated in the photo via formation step (2), the smear may be removed with the roughening liquid. The roughening treatment can be performed simultaneously with the removal of the smear (desmear).

Examples of the roughening liquid include a chromium/sulfuric acid roughening liquid, an alkaline permanganate roughening liquid (for example, a sodium permanganate roughening liquid), and a sodium fluoride/chromium/sulfuric acid roughening liquid.

An uneven anchor is formed on the via and the surface of the interlayer insulating layer through the roughening treatment.

### (Circuit Pattern Formation Step (4))

The circuit pattern formation step (4) is a step of forming a circuit pattern on the interlayer insulating layer after the roughening treatment step (3).

From the viewpoint of forming a micro wiring, it is preferred to carry out the formation of the circuit pattern through a semi-additive process. According to the semi-additive process, conduction of the via is achieved along with the formation of the circuit pattern.

In the semi-additive process, the via bottom, the via wall surface, and the surface of the interlayer insulating layer after the roughening treatment step (3) are entirely subjected to an electroless copper plating treatment using a palladium catalyst or the like to form a seed layer 105. The seed layer 105 is one for forming a power supply layer for the purpose of performing electrolytic copper plating and is preferably formed in a thickness of about 0.1 to 2.0 μm. When the thickness of the seed layer 105 is 0.1 μm or more, there is a tendency that reduction in connection reliability upon electrolytic copper plating can be suppressed, and when the thickness is 2.0 μm or less, there is a tendency that the damage given to the wiring in etching is suppressed without the need to increase the etching amount in flash etching of the seed layer between wirings.

The electroless copper plating treatment is performed by depositing metallic copper on the via and the surface of the interlayer insulating layer through a reaction between copper ions and a reducing agent.

As an electroless plating treatment method and an electroplating treatment method, known methods can be applied, and the methods are not particular limited.

As the electroless copper plating solution, a commercial product can be used. Examples of the commercial product include “MSK-DK” manufactured by Atotech Japan K.K.; and “THRU-CUP (registered trademark) PEA series” manufactured by C. Uyemura & Co., Ltd.

After performing the electroless copper plating treatment, a dry film resist is thermal pressure-bonded on the electroless copper plating by using a roll laminator. The thickness of the dry film resist must be made higher than the height of the wiring after electrolytic copper plating, and from this point of view, a dry film resist having a thickness of 5 to 30 μm is preferred. As for the dry film resist, for example, “PHOTEC (registered trademark)” series manufactured by Showa Denko Materials Co., Ltd. is used.

After the thermal pressure bonding of the dry film resist, the dry film resist is exposed, for example, through a mask having a desired wiring pattern drawn therein. The exposure can be performed by using the same apparatus and light source as those which may be used in forming a via on the photosensitive resin film. After the exposure, development of the dry film resist is performed using an alkaline aqueous solution to remove the unexposed portion, whereby a resist pattern 106 is formed. Thereafter, as required, a work of removing a development residue of the dry film resist using a plasma or the like may be performed.

After the development, by performing electrolytic copper plating, a copper circuit layer (circuit pattern) 107 is formed and via filling is performed.

After the electrolytic copper plating, the dry film resist is stripped off by using an alkaline aqueous solution or an amine-based stripping agent. After stripping off the dry film resist, removal of the seed layer between the wirings (flash etching) is performed. The flash etching is performed by using an acidic solution and an oxidative solution, such as sulfuric acid and hydrogen peroxide. After the flash etching, as required, removal of palladium and the like deposited in a portion between the wirings is performed. The removal of palladium can be performed preferably by using an acidic solution, such as nitric acid or hydrochloric acid.

After stripping of the dry film resist or after the flash etching step, a post-baking treatment is preferably performed. According to the post-baking treatment, an unreacted thermosetting component can be thoroughly thermally cured, whereby the insulation reliability, the curing characteristics, and the adhesion strength to copper plating tend to be improved. Although the thermal curing conditions vary depending on the kind of the resin composition, and the like, it is preferred that the curing temperature is 150 to 240° C., and the curing time is 15 to 100 minutes. By the post-baking treatment, a series of production steps of the multilayered printed wiring board 100A by the photo via method is accomplished, however, the substrate is produced by repeating this process according to the required number of the interlayer insulating layers. Then, a solder resist layer 108 is preferably formed on the outermost layer.

Hereinabove, a method for producing a multilayered printed wiring board in which a via is formed using the photosensitive resin composition of this embodiment has been described. Since the photosensitive resin composition of this embodiment is excellent in pattern resolution, for example, it is also suitable for forming a cavity for internally containing a chip, a passive element, or the like. For example, the cavity can be suitably formed in the same manner as in the aforementioned explanation regarding the multilayered printed wiring board except that the drawing pattern in exposing the photosensitive resin film to thus form a pattern is one capable of forming a desired cavity. Furthermore, the photosensitive resin composition of this embodiment is also useful for solder resist.

### [Semiconductor Package]

The present disclosure also provides a semiconductor package including the multilayered printed wiring board of this embodiment and a semiconductor element. The semiconductor package of this embodiment can be produced by mounting the semiconductor element, such as a semiconductor chip or a memory, at a predetermined position of the multilayered printed wiring board of this embodiment and sealing the semiconductor element with a sealing resin or the like.

### EXAMPLES

Hereinafter, this embodiment will be described in more detail with reference to Examples, but the present disclosure is not limited to these Examples. The acid value and the weight average molecular weight of the component (A) were measured according to the following methods, and the true densities of the component (X), a component (X′), and the component (E) were measured according to the following method. Characteristics of the photosensitive resin composition obtained by each example were evaluated according to the following methods.

### <Measurement Method of Acid Value>

The acid value of the component (A) was calculated from the amount of an aqueous potassium hydroxide solution taken for neutralizing the component (A).

### <Measurement Method of Weight Average Molecular Weight>

The weight average molecular weight of the component (A) was determined as follows: a measurement was performed with a GPC measurement apparatus and measurement conditions and the result was subjected to a calculation based on a calibration curve of standard polystyrenes to determine the weight average molecular weight. The calibration curve was created using a 5-sample set (“PStQuick MP-H” and “PStQuick B”, manufactured by Tosoh Corporation) as the standard polystyrenes.

### (GPC Measurement Apparatus)

Apparatus: High-speed GPC apparatus “HCL-8320GPC”, with a differential refractometer or UV as a detector, manufactured by Tosoh Corporation
Column: Column TSKgel SuperMultipore HZ-H (column length: 15 cm, column inner diameter: 4.6 mm), manufactured by Tosoh Corporation

### (Measurement Conditions)

Solvent: Tetrahydrofuran (THF)
Measurement temperature: 40° C.
Flow rate: 0.35 mL/min
Sample concentration: 10 mg/5 mL of THF
Injection volume: 20 μL

### <Measurement Method of True Density and Calculation Method of Hollow Rate>

### (True Density)

First, the component (X) or component (X′) was placed in a mortar and was grinded with a pestle to thereby obtain particles of the component (X) or component (X′) having a particle size of 0.1 μm or less. The grinded component (X) or component (X′) was charged into a 1 cm³ cell of a dry automatic density meter “AccuPycII 1340” (manufactured by Shimadzu Corporation) up to the 80-percent height. The weight of the cell charged with the component was measured and the weight of the cell itself was subtracted therefrom to determine the weight of the component charged into the cell.

Next, the cell charged with the component was set into the dry automatic density meter, and then, the weight of the component was input. The cell set in the dry automatic density meter was allowed to stand at normal temperature and in nitrogen atmosphere for 1 hour, then, a measurement was performed 10 times, and the average was determined. The average was taken as the true density.

### (Hollow Rate)

Separately from the measurement of the true density, an apparent density (specific gravity) of the component (X) or component (X′) was measured with the dry automatic density meter. The apparent density (specific gravity) was measured as follows. The component (X) or component (X′) (not grinded but in the state as it was) was charged into a 1 cm³ cell of a dry automatic density meter “AccuPycII 1340” (manufactured by Shimadzu Corporation) up to the 80-percent height. The weight of the cell charged with the component was measured and the weight of the cell itself was subtracted therefrom to determine the weight of the component charged into the cell. Next, the cell charged with the component was set into the dry automatic density meter, and then, the weight of the component was input. The cell set in the dry automatic density meter was allowed to stand at normal temperature and in nitrogen atmosphere for 1 hour, then, a measurement was performed 10 times, and the average was determined. The average was taken as the apparent density (specific gravity).

The apparent density (specific gravity) and the true density obtained as above were used to calculate the hollow rate according to the following formula.

$$Hollow rate ( \% ) = 100 \times \{ 1 - ( apparent density ) / ( true density ) \}$$

### [1. Evaluation of Dielectric Constant (Dk)]

The protective film was stripped from the photosensitive resin film and two resulting photosensitive resin films were bonded to each other and, with the carrier film remaining on both surfaces thereof, the bonded films were irradiated using a UV conveyer exposure machine at 2 J/cm² (wavelength: 365 nm). This was subjected to a heat treatment with a hot air circulation drier at 170° C. for 1 hour and was cut into a size of 7 cm×10 cm to prepare an evaluation sample.

The obtained evaluation sample was dried with a hot air circulation dryer at 105° C. for 10 minutes, and then, the dielectric constant (Dk) was measured in the 10 GHz band by a split post dielectric resonator method (SPDR method).

### [2. Evaluation of Adhesion Strength to Copper Plating and Evaluation of Presence or Absence of Occurrence of Plating Detachment]

While striping the protective film from the “photosensitive resin film with the carrier film and the protective film bonded thereto” produced in each Example and Comparative Example, lamination was performed on a copper-clad laminate substrate having a thickness of 1.0 mm using a pressure-type vacuum laminator (manufactured by Meiki Co., Ltd., tradename “MVLP-500”) at a bonding pressure of 0.4 MPa, a press hot plate temperature of 80° C., a vacuum drawing time of 25 seconds, a laminate press time of 25 seconds, and an air pressure of 4 kPa or less, thereby producing a laminated body.

The obtained laminated body was subjected to entire surface exposure using a parallel light exposure machine (manufactured by ORC MANUFACTURING CO., LTD., tradename “EXM-1201”) with an ultrahigh voltage mercury lamp as a light source at 400 mJ/cm² (wavelength: 365 nm). Next, the laminated body was subjected to exposure using a UV exposure apparatus at an exposure amount of 2,000 mJ/cm² (wavelength: 365 nm), and then, heated at 170° C. for 1 hour, thereby producing a “laminated body for evaluation” in which a cured product was formed on a copper-clad laminate substrate.

Then, firstly, as a swelling liquid, an aqueous solution of “diethylene glycol monobutyl ether: 200 ml/L and sodium hydroxide: 5 g/L” was prepared, and then, was heated to 70° C., and the laminated body for evaluation was dipped therein for 10 minutes. Next, as a roughening liquid, an aqueous solution of potassium permanganate: 60 g/L and sodium hydroxide: 40 g/L was prepared, and then, was heated to 70° C., and the laminated body for evaluation was dipped therein for 15 minutes. Subsequently, an aqueous solution of a neutralizing liquid (stannous chloride (SnCl₂): 30 g/L and hydrogen chloride: 300 ml/L) was prepared and then, was heated to 40° C., and the laminated body for evaluation was dipped therein for 5 minutes, thereby reducing potassium permanganate. As described above, the surface of the cured product of the laminated body for evaluation was subjected to a desmear treatment.

Next, the desmear-treated surface of the cured product of the laminated body for evaluation was treated with an alkaline cleaner “Cleaner Securigant 902” (tradename, manufactured by Atotech Japan) at 60° C. for 5 minutes, followed by degrease cleansing. After cleansing, the desmear-treated cured product was treated with a predip liquid “Predip Neogant B” (tradename, manufactured by Atotech Japan) at 23° C. for 1 minute. After that, the cured product was treated with an activator liquid “Activator Neogant 834” (tradename, manufactured by Atotech Japan) at 35° C. for 5 minutes and then, the cured product was treated with a reducing liquid “Reducer Neogant WA” (tradename, manufactured by Atotech Japan) at 30° C. for 5 minutes.

The thus obtained laminated body for evaluation was put in a chemical copper liquid (“Basic Printgant MSK-DK”, “Copper Printgant MSK”, “Stabilizer Printgant MSK” (all tradename, manufactured by Atotech Japan)), and an electroless plating was performed until a plating thickness of about 0.5 μm was achieved. After the electroless plating, for removing the remaining hydrogen gas, an annealing treatment was performed at a temperature of 120° C. for 30 minutes. Then, a copper sulfate electroplating was performed, followed by an annealing treatment at 180° C. for 60 minutes to form a conductive layer having a thickness of 25 μm.

For the laminated body for evaluation in which a conductive layer was formed as described above, a vertical peel strength was measured according to JIS C6481 (1996) at 23° C., and was evaluated according to the following evaluation criteria.
A: The adhesion strength to copper plating was 0.4 kN/m or more.
B: The adhesion strength to copper plating was 0.3 kN/m or more and less than 0.4 kN/m.
C: The adhesion strength to copper plating was more than 0.1 kN/m and less than 0.3 kN/m.
D: The adhesion strength to copper plating was 0.1 kN/m or less.

The surface of the laminated body for evaluation after the annealing treatment was visually observed to check the presence or absence of occurrence of plating detachment. When occurrence of plating detachment is present, unevenness has been generated on the plating surface and when occurrence of the plating detachment is absent, a smooth plating surface has been produced.

### Preparation of Photosensitive Resin Composition

### Examples 1 to 5, Comparative Examples 1 to 3

### (1) Production of Photosensitive Resin Composition

According to the blending composition shown in Table 1 (the unit of the numerical values in the table is parts by mass, and in the case of a solution, the numerical values are amounts in terms of a solid component), a composition was formulated, and then, was kneaded with a three-roll mill. Subsequently, methyl ethyl ketone was added thereto for the purpose of achieving a solid concentration of 65% by mass, whereby a photosensitive resin composition was obtained.

### (2) Production of Photosensitive Resin Film

A polyethylene terephthalate film (manufactured by Teijin Limited, tradename “G2-16”) having a thickness of 16 μm was used as a carrier film. On the carrier film, the photosensitive resin composition prepared in each Example was applied with such adjustment as to give a film thickness after drying of 25 μm, and was dried using a hot air convection dryer at 100° C. for 10 minutes, thereby forming a photosensitive resin film (photosensitive layer). Subsequently, on a surface of the photosensitive resin film (photosensitive layer) opposite to the side in contact with the carrier film, a polyethylene film (manufactured by Tamapoly Co., Ltd., tradename “NF-15”) was bonded as a protective film, whereby a photosensitive resin film having a carrier film and a protective film bonded thereto was produced.

The produced photosensitive resin film was used to perform the evaluations according to the aforementioned methods. The results are shown in Table 1.

TABLE 1

| | | | | | | | | Comparative | | |
|---|---|---|---|---|---|---|---|---|---|---|
| Components of photosensitive resin | | | Example | | | | | Example | | |
| composition | | | 1 | 2 | 3 | 4 | 5 | 1 | 2 | 3 |
| (A) | Photopolymerizable | A1 | 8.0 | 8.0 | 8.0 | 8.0 | 8.0 | 8.0 | 8.0 | 8.0 |
| | compound | | | | | | | | | |
| | having | | | | | | | | | |
| | ethylenically | | | | | | | | | |
| | unsaturated | | | | | | | | | |
| | group and acidic | | | | | | | | | |
| | substituent | | | | | | | | | |
| (B) | Thermosetting | B1 | 3.4 | 3.4 | 3.4 | 3.4 | 3.4 | 3.4 | 3.4 | 3.4 |
| | resin | B2 | 2.3 | 2.3 | 2.3 | 2.3 | 2.3 | 2.3 | 2.3 | 2.3 |
| (C) | Crosslinking | C1 | 3.8 | 3.8 | 3.8 | 3.8 | 3.8 | 3.8 | 3.8 | 3.8 |
| | agent | | | | | | | | | |
| (D) | Elastomer | D1 | 1.3 | 1.3 | 1.3 | 1.3 | 1.3 | 1.3 | 1.3 | 1.3 |
| | | D2 | 0.4 | 0.4 | 0.4 | 0.4 | 0.4 | 0.4 | 0.4 | 0.4 |
| (X) | Inorganic filler | X1 | 6 | | 11 | 3 | | | | |
| | of solid particles | (0.7 μm) | (20) | | (35) | (10) | | | | |
| | having true | X2 | | 6 | | | | | | |
| | density of 1,500 | (1.5 μm) | | (20) | | | | | | |
| | kg/m³ or less | X3 | | | | | 6 | | | |
| | | (3.0 μm) | | | | | (20) | | | |
| (X′) | Inorganic filler | X′1 | | | | | | 9.8 | | |
| | of solid particles | (0.5 μm) | | | | | | (20) | | |
| | having true | | | | | | | | | |
| | density of more | | | | | | | | | |
| | than 1,500 kg/m³ | | | | | | | | | |
| | Inorganic filler | X′2 | | | | | | | | 9.8 |
| | of hollow | (0.7 μm) | | | | | | | | (20) |
| | particles having | | | | | | | | | |
| | true density of | | | | | | | | | |
| | 1,500 kg/m³ or | | | | | | | | | |
| | less | | | | | | | | | |
| (E) | Organic filler | PTFE | 7.5 | 7.5 | | 12 | 7.5 | 7.5 | 25 | 7.5 |
| | | (200 nm) | (15) | (15) | | (25) | (15) | (15) | (50) | (15) |
| (F) | Curing agent | F1 | 0.1 | 0.1 | 0.1 | 0.1 | 0.1 | 0.1 | 0.1 | 0.1 |
| (G) | Curing | G1 | 0.2 | 0.2 | 0.2 | 0.2 | 0.2 | 0.2 | 0.2 | 0.2 |
| | accelerator | | | | | | | | | |
| (H) | Photopolymerization | H1 | 0.004 | 0.004 | 0.004 | 0.004 | 0.004 | 0.004 | 0.004 | 0.004 |
| | initiator | H2 | 0.044 | 0.044 | 0.044 | 0.044 | 0.044 | 0.044 | 0.044 | 0.044 |
| (I) | Photosensitizer | I1 | 0.1 | 0.1 | 0.1 | 0.1 | 0.1 | 0.1 | 0.1 | 0.1 |
| (J) | Polymerization | 4-t-butyl | 0.1 | 0.1 | 0.1 | 0.1 | 0.1 | 0.1 | 0.1 | 0.1 |
| | inhibitor | catechol | | | | | | | | |
| | Foam stabilizer | SH-193 | 0.03 | 0.03 | 0.03 | 0.03 | 0.03 | 0.03 | 0.03 | 0.03 |
| Evaluation | Dielectric | (10 | 2.4 | 2.5 | 2.5 | 2.4 | 2.4 | 2.8 | 2.2 | 2.2 |
| results | constant (Dk) | GHz) | | | | | | | | |
| | Adhesion | kN/m | 0.4 | 0.5 | 0.4 | 0.4 | 0.3 | 0.4 | ≤0.1 | ≤0.1 |
| | strength to | Evaluation | A | A | A | A | B | A | D | D |
| | copper plating | | | | | | | | | |

| | | | | | | | | |
|---|---|---|---|---|---|---|---|---|
| Presence or absence of | absence | absence | absence | absence | absence | absence | presence | presence |
| occurrence of plating | | | | | | | | |
| detachment | | | | | | | | |

The unit of content is parts by mass, and in the case of solution or dispersion, the content corresponds to an amount in terms of the solid component.
The content described in the parentheses is in “% by volume” based on the total amount of solid components.

The components used in Table 1 are as follows.

### [(A) Photopolymerizable Compound Having Ethylenically Unsaturated Group and Acidic Substituent]

A1; “ZXR-1935H” (manufactured by Nippon Kayaku Co., Ltd., acid value; 110 mgKOH/g, weight average molecular weight; 2,000)

### [(B) Thermosetting Resin]

B1; “Epotote (registered tradename) ESN-475V” (manufactured by NIPPON STEEL Chemical & Material Co., Ltd., naphthol-type epoxy resin, epoxy equivalent; 325 g/eq)
B2; “NC-3000L” (manufactured by Nippon Kayaku Co., Ltd., biphenylaralkyl-type epoxy resin, epoxy equivalent; 272 g/eq)

### [(C) Crosslinking Agent]

C1; “TMPTA” (trimethylolpropane triacrylate)

### [(D) Elastomer]

D1; “Ricon (registered tradename) 131MA17” (manufactured by Cray Valley, maleic acid-modified polybutadiene, number average molecular weight: 54,000 (value in catalog))
D2; “Ricon (registered tradename) 100” (manufactured by Cray Valley, butadiene-styrene random copolymer, number average molecular weight: 45,000 (value in catalog))
   [(X) Inorganic Filler that is Solid Particles Having True Density of 1,500 kg/m³ or Less]
X1; Spherical fused silica that is solid particles having a true density of 1,350 kg/m³ (volume average particle size; 0.7 μm), treated with a silane coupling agent, hollow rate=39%
X2; Spherical fused silica that is solid particles having a true density of 1,350 kg/m³ (volume average particle size; 1.5 μm), treated with a silane coupling agent, hollow rate=39%
X3; Spherical fused silica that is solid particles having a true density of 1,350 kg/m³ (volume average particle size; 3.0 μm), treated with a silane coupling agent, hollow rate=39%
   [(X′) Inorganic Filler Other than Component (X)]
   (Inorganic Filler that is Solid Particles Having a True Density of More than 1,500 kg/m³)
X′1; Spherical fused silica that is solid particles having a true density of 2,210 kg/m³ (volume average particle size; 0.5 μm), treated with a silane coupling agent, hollow rate=0%
   (Inorganic Filler that is Hollow Particles Having a True Density of 1,500 kg/m³ or Less)
X′2; Spherical fused silica that is hollow particles having a true density of 620 kg/m³ (volume average particle size; 0.7 μm), treated with a silane coupling agent, hollow rate=72%

### [(E) Organic Filler]

PTFE; “M-7226EX” (manufactured by MORIMURA CHEMICALS LTD., volume average particle size; 200 nm)

### [(F) Curing Agent]

F1; “Phenolite (registered tradename) LA7052” (manufactured by DIC Corporation, melamine, novolak-type phenol resin modified with benzoguanamine or the like, hydroxy group equivalent; 120 g/eq)

### [(G) Curing Accelerator]

G1; 2-Phenyl-1-benzyl-1H-imidazole (imidazole-based compound)

### [(H) Photopolymerization Initiator]

H1; 1-[9-Ethyl-6-(2-methylbenzoyl)-9H-carbazol-3-yl]ethanone 1-(0-acetyl oxime) (oxime ester-based compound)
H2; bis(2,4,6-trimethylbenzoyl)phenylphosphine oxide (acylphosphine oxide-based compound)

### [(I) Photosensitizer]

I1; 4,4′-bis(diethylamino)benzophenone

### [(J) Additive]

4-t-Butyl catechol; polymerization inhibitor
“SH-193” (manufactured by Dow Toray Co., Ltd., silicone-based foam stabilizer)

It can be found from Table 1 that in the photosensitive resin compositions of Examples 1 to 5 of this embodiment, the dielectric constant could be decreased while maintaining a high adhesion strength to copper plating, as compared with in the photosensitive resin composition of Comparative Example 1 in which an inorganic filler having a true density of 2,210 kg/m³ was used.

It was found that, in the photosensitive resin composition of Comparative Example 2 in which a large amount of PTFE was incorporated for the purpose of significantly decreasing the dielectric constant, although the purpose was achieved, the adhesion strength to copper plating was significantly decreased and plating detachment was liable to occur.

Even if the true density was 1,500 kg/m³ or less, in the case of hollow particles, the adhesion strength to copper plating was significantly decreased and plating detachment occurred.

### REFERENCE SIGNS LIST

100A: Multilayered printed wiring board
101: Substrate
102: Circuit pattern
103: Interlayer insulating layer
104: Via (via hole)
105: Seed layer
106: Resist pattern
107: Copper circuit layer
108: Solder resist layer

1. A photosensitive resin composition comprising (X) an inorganic filler that is solid particles having a true density of 1,500 kg/m³ or less.

2. The photosensitive resin composition according to claim 1, wherein the component (X) has a volume average particle size of 0.3 to 3 μm.

3. The photosensitive resin composition according to claim 1, wherein the component (X) is contained in an amount of 1 to 45% by volume based on a total amount of solid components in the photosensitive resin composition.

4. The photosensitive resin composition according to claim 1, further comprising (A) a photopolymerizable compound having an ethylenically unsaturated group and an acidic substituent and (B) a thermosetting resin.

5. The photosensitive resin composition according to claim 4, wherein the component (A) comprises an alicyclic skeleton represented by the following general formula (A-1): 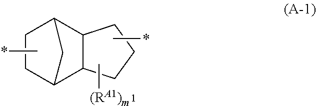
wherein R^{A1} represents an alkyl group having 1 to 12 carbon atoms and may be substituted on any site in the alicyclic skeleton, m¹ is an integer of 0 to 6, and * is a bonding site to another structure.

6. The photosensitive resin composition according to claim 4, wherein the photosensitive resin composition has an equivalent ratio of an epoxy group of the component (B) to the acidic substituent of the component (A) [epoxy group/acidic substituent] of 0.5 to 6.0.

7. The photosensitive resin composition according to claim 1, further comprising (C) a crosslinking agent.

8. The photosensitive resin composition according to claim 1, further comprising (D) an elastomer.

9. The photosensitive resin composition according to claim 1, further comprising (E) an organic filler.

10. The photosensitive resin composition according to claim 9, wherein the component (E) comprises resin particles formed of at least one selected from the group consisting of a resin having a fluorine atom, polyethylene, polypropylene, polystyrene, polyphenylene ether, and a silicone.

11. The photosensitive resin composition according to claim 9, wherein the component (E) is contained in an amount of 1 to 45% by volume based on the total amount of solid components in the photosensitive resin composition.

12. The photosensitive resin composition according to claim 1, further comprising (H) a photopolymerization initiator.

13. The photosensitive resin composition according to claim 12, wherein two or more kinds of the component (H) are contained.

14. A photopolymerization initiator for photo-via formation, comprising the photosensitive resin composition according to claim 1.

15. A photosensitive resin film formed by using the photosensitive resin composition according to claim 1.

16. A multilayered printed wiring board comprising an interlayer insulating layer that is formed by using the photosensitive resin composition according to claim 1.

17. A semiconductor package comprising the multilayered printed wiring board according to claim 16 and a semiconductor element.

18. A method for producing a multilayered printed wiring board, the method comprising the flowing (1), (2), and (4):
(1): laminating the photosensitive resin film according to claim 15 on one surface or both surfaces of a circuit substrate;
(2): exposing and developing the photosensitive resin film laminated in (1) to thereby form an interlayer insulating layer having a via;
(4): forming a circuit pattern on the interlayer insulating layer.
